(19) United States
(12) Patent Application Publication
(10) Pub. No.: US 2026/0013276 A1
(43) Pub. Date: Jan. 8, 2026

(54) LIGHT EMITTING ELEMENT AND DISPLAY DEVICE INCLUDING THE SAME

(71) Applicant: Samsung Display Co., LTD., Yongin-si (KR)

(72) Inventors: Hyeong Su CHOI, Yongin-si (KR); In Hyuk KIM, Yongin-si (KR); Chul Jong YOO, Yongin-si (KR); Da Hye YOON, Yongin-si (KR); Tae Ha JIN, Yongin-si (KR); Hye Won HONG, Yongin-si (KR)

(21) Appl. No.: 19/078,424

(22) Filed: Mar. 13, 2025

(30) Foreign Application Priority Data
Jul. 4, 2024 (KR) 10-2024-0087929

(51) Int. Cl. H10H 20/84; H01L 25/075; H10H 20/01; H10H 20/821; H10H 29/34

(52) U.S. Cl. CPC H10H 20/84; H10H 20/017; H10H 20/034; H10H 20/821; H10H 29/34; H01L 25/0753

(57) ABSTRACT

A light emitting element includes a first semiconductor layer doped with an N-type dopant, a second semiconductor layer disposed on the first semiconductor layer and doped with a P-type dopant, an active layer disposed between the first semiconductor layer and the second semiconductor layer, an electrode layer disposed on the second semiconductor layer, and a multilayer insulating film surrounding at least an outer surface of the active layer and including two or more layers, wherein any one insulating film of the multilayer insulating film that is in contact with at least the outer surface of the active layer has a carbon content of about 3% to about 30%.

This application claims priority to Korean Patent Application No. 10-2024-0087929, filed on Jul. 4, 2024, and all the benefits accruing therefrom under 35 U.S.C. § 119, the content of which in its entirety is herein incorporated by reference.

### BACKGROUND

### 1. Field

The present invention relates to a light emitting element, and more particularly to a light emitting element and a display device including the same.

### 2. Description of the Related Art

The importance of a display device is increasing with the development of multimedia. Accordingly, various types of display devices such as an organic light emitting display (OLED) and a liquid crystal display (LCD) are being used.

There exists a self-light emitting display device including a light emitting element as a device for displaying an image of the display device. The self-light emitting display device includes an organic light emitting display device using an organic material, which is a light emitting element being used as a light emitting material, or an inorganic light emitting display device using an inorganic material as a light emitting material.

### SUMMARY

Aspects of the invention provide a light emitting element with improved reliability and a display device including the same.

However, aspects of the invention are not restricted to those set forth herein. The above and other aspects of the invention will become more apparent to one of ordinary skill in the art to which the invention pertains by referencing the detailed description of the invention given below.

According to an aspect of the invention, a light emitting element includes a first semiconductor layer doped with an N-type dopant, a second semiconductor layer disposed on the first semiconductor layer and doped with a P-type dopant, an active layer disposed between the first semiconductor layer and the second semiconductor layer, an electrode layer disposed on the second semiconductor layer, and a multilayer insulating film surrounding at least an outer surface of the active layer and including two or more layers, wherein any one insulating film of the multilayer insulating film in contact with at least the outer surface of the active layer has a carbon content of about 3% to about 30%.

In an embodiment, the multilayer insulating film includes a first insulating film in contact with at least the outer surface of the active layer, and a second insulating film surrounding an outer surface of the first insulating film, wherein the first insulating film has a carbon content of about 3% to about 30%.

In an embodiment, the insulating film in contact with at least the outer surface of the active layer includes any one selected from the group consisting of zirconium oxide (ZrO₂), hafnium oxide (HfO₂), lanthanum oxide (La₂O₃), tantalum oxide (Ta₂O₅), yttrium oxide (Y₂O₃), niobium oxide (Nb₂O₅), and titanium oxide (TiO₂).

In an embodiment, the insulating film includes zirconium oxide (ZrO₂) or yttrium oxide (Y₂O₃) and has a film density of about 3 to about 5.

In an embodiment, the insulating film includes hafnium oxide (HfO₂) or tantalum oxide (Ta₂O₅) and has a film density of about 6 to about 8.

In an embodiment, the insulating film includes lanthanum oxide (La₂O₃) and has a film density of about 4 to about 6.

In an embodiment, the insulating film includes niobium oxide (Nb₂O₅) and has a film density of about 2.5 to about 4.5.

In an embodiment, the insulating film includes titanium oxide (TiO₂) and has a film density of about 2 to about 4.

In an embodiment, the active layer has a diameter of about 0.5 to about 6 μm, and has a luminance maintenance rate of about 90% or more compared to an initial luminance when driven continuously for about 300 hours with a first driving current applied.

In an embodiment, light emitted from the active layer has a peak wavelength in the range of about 440 nm to about 480 nm.

In an embodiment, the first driving current is about 50 A/cm² or more.

According to an embodiment, a light emitting element includes a light emitting structure including a first semiconductor layer, an active layer, and a second semiconductor layer sequentially disposed along one direction, a multilayer insulating film surrounding an outer surface of the light emitting structure and including at least two layers of insulating film, and a protective film surrounding an outer surface of the multilayer insulating film and including at least one insulating film, wherein a carbon content in any one insulating film of the multilayer insulating film that is in contact with the outer surface of the light emitting structure is greater than a carbon content in an insulating film that forms an outermost portion of the protective film.

In an embodiment, the carbon content in the insulating film of the multilayer insulating film in contact with the outer surface of the light emitting structure is about 3% to about 30%, wherein the carbon content in the insulating film that forms the outermost portion of the protective film is about 3% to about 30%.

In an embodiment, the multilayer insulating film includes a first insulating film surrounding the outer surface of the light emitting structure, a second insulating film surrounding an outer surface of the first insulating film, and a third insulating film surrounding an outer surface of the second insulating film, wherein a carbon content in the first insulating film is about 3% to about 30%.

In an embodiment, the protective film includes a fourth insulating film surrounding an outer surface of the third insulating film, wherein a carbon content in the fourth insulating film is about 3% to about 30%, and wherein the carbon content in the first insulating film is greater than the carbon content in the fourth insulating film.

In an embodiment, the protective film includes a fourth insulating film surrounding an outer surface of the third insulating film and a fifth insulating film surrounding an outer surface of the fourth insulating film, wherein a carbon content in the fifth insulating film is about 3% to about 30%, and wherein the carbon content in the first insulating film is greater than the carbon content in the fifth insulating film.

According to an embodiment, a display device includes a first electrode and a second electrode disposed to be spaced apart from each other on a substrate, and a light emitting element electrically connected to the first electrode and the second electrode, and having a shape extending in one direction, wherein the light emitting element includes a light emitting structure including a first semiconductor layer, an active layer, and a second semiconductor layer sequentially disposed along one direction, and a multilayer insulating film surrounding an outer surface of the light emitting structure and including at least two layers of insulating film, wherein any one of the insulating films of the multilayer insulating film in contact with the outer surface of the light emitting structure has a carbon content of about 3% to about 30%.

In an embodiment, the insulating film in contact with the outer surface of the light emitting structure includes any one selected from the group consisting of zirconium oxide (ZrO₂), hafnium oxide (HfO₂), lanthanum oxide (La₂O₃), tantalum oxide (Ta₂O₅), yttrium oxide (Y₂O₃), niobium oxide (Nb₂O₅), and titanium oxide (TiO₂).

In an embodiment, the display device further includes a protective film surrounding an outer surface of the multilayer insulating film and including at least one insulating film, wherein a carbon content in any one insulating film of the multilayer insulating film in contact with the outer surface of the light emitting structure is greater than a carbon content in an insulating film disposed at an outermost portion of the protective film.

In an embodiment, the light emitting structure has a diameter of about 0.5 μm to about 6 μm, and the light emitting element has a luminance maintenance rate of about 90% or more compared to an initial luminance when driven continuously for about 300 hours with a first driving current of about 50 A/cm² or more applied.

In the light emitting element and the display device including the same, according to an embodiment, the reliability of the light emitting element may be improved by reducing the carbon content of the insulating film in contact with the light emitting structure and improving the film quality of the insulating film.

However, the effects of the invention are not restricted to the embodiments set forth herein. The above and other effects of the invention will become more apparent to one of ordinary skill in the art to which the invention pertains.

### BRIEF DESCRIPTION OF THE DRAWINGS

The above and other aspects and features of the invention will become more apparent by describing in detail embodiments thereof with reference to the attached drawings, in which:

FIG. 1 is a perspective view schematically illustrating a light emitting element, according to an embodiment;

FIG. 2 is a cross-sectional view schematically illustrating the light emitting element, according to an embodiment;

FIG. 3 is a cross-sectional view illustrating an example of the light emitting element taken along line I-I′ of FIG. 1, according to an embodiment;

FIG. 4 is a cross-sectional view illustrating another example of the light emitting element taken along line I-I′ of FIG. 1, according to an embodiment;

FIG. 5 is a graph illustrating a luminance maintenance rate of the light emitting element over time, according to an embodiment;

FIG. 6 is a flowchart illustrating a method for manufacturing a light emitting element, according to an embodiment;

FIG. 7 is a cross-sectional view sequentially illustrating a process of manufacturing a light emitting element, according to an embodiment;

FIG. 8 is a cross-sectional view sequentially illustrating a process of manufacturing a light emitting element, according to an embodiment;

FIG. 9 is a cross-sectional view sequentially illustrating a process of manufacturing a light emitting element, according to an embodiment;

FIG. 10 is a cross-sectional view sequentially illustrating a process of manufacturing a light emitting element, according to an embodiment;

FIG. 11 is a cross-sectional view sequentially illustrating a process of manufacturing a light emitting element, according to an embodiment;

FIG. 12 is a cross-sectional view sequentially illustrating a process of manufacturing a light emitting element, according to an embodiment;

FIG. 13 is a cross-sectional view sequentially illustrating a process of manufacturing a light emitting element, according to an embodiment;

FIG. 14 is a cross-sectional view sequentially illustrating a process of manufacturing a light emitting element, according to an embodiment;

FIG. 15 is a cross-sectional view sequentially illustrating a process of manufacturing a light emitting element, according to an embodiment;

FIG. 16 is a cross-sectional view sequentially illustrating a process of manufacturing a light emitting element, according to an embodiment;

FIG. 17 is a cross-sectional view of a display device, according to an embodiment;

FIG. 18 is a cross-sectional view of a display device, according to another embodiment;

FIG. 19 is a cross-sectional view of a display device, according to another embodiment;

FIG. 20 is a graphical view illustrating electronic devices including a display device, according to an embodiment;

FIG. 21 is a graphical view illustrating electronic devices including a display device, according to an embodiment;

FIG. 22 is a graphical view illustrating electronic devices including a display device, according to an embodiment;

FIG. 23 is a graphical view illustrating electronic devices including a display device, according to an embodiment;

FIG. 24 is a graphical view illustrating electronic devices including a display device, according to an embodiment; and

FIG. 25 is a graphical view illustrating electronic devices including a display device, according to an embodiment.

### DETAILED DESCRIPTION

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this invention will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Each of the features of the various embodiments of the invention may be combined with each other, in part or in whole, and technically various interlocking and driving are possible. Each embodiment may be implemented independently of each other or may be implemented together in an association.

Hereinafter, embodiments of the invention will be described with reference to the accompanying drawings.

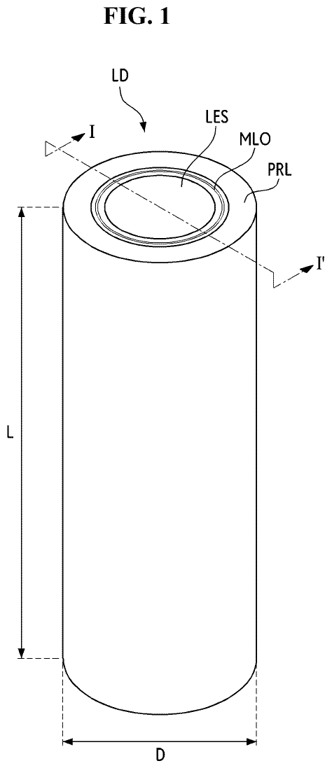

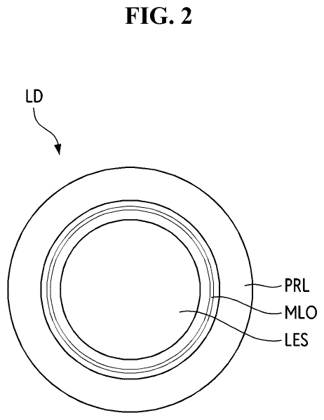

FIG. 1 is a perspective view schematically illustrating a light emitting element, according to an embodiment. FIG. 2 is a cross-sectional view schematically illustrating the light emitting element, according to an embodiment.

In an embodiment and referring to FIGS. 1 and 2, a light emitting element LD may include a light emitting structure LES, a multilayer insulating film MLO, and a protective film PRL.

In an embodiment, the light emitting element LD may be a light emitting diode, and specifically, the light emitting element LD may be an inorganic light emitting diode made of an inorganic material. The light emitting element LD may be disposed between two opposing electrodes and may emit light by electrical signals applied from the electrodes.

The light emitting element LD, according to an embodiment, may have a shape extending in one direction. The light emitting element LD may have a shape such as a cylinder, a rod, a wire, or a tube. However, the shape of the light emitting element LD is not limited thereto and the light emitting element LD may have various shapes such as having a polygonal prismatic shape such as a cubic shape, a rectangular parallelepiped shape, or a hexagonal prismatic shape or having a shape extending in one direction and having a partially inclined outer surface.

In an embodiment, the light emitting element LD may have a size ranging from nanometers to micrometers. For example, the light emitting element LD may have a diameter D (or a width in cross section) and/or a length L ranging from nanometers to micrometers, respectively. As an example, the light emitting element LD may have a diameter D and/or a length L ranging from approximately tens of nanometers to tens of micrometers.

In an embodiment, the structure, shape, size, and/or type of the light emitting element LD may be changed depending on the embodiments. For example, the structure, shape, size, and/or type of the light emitting element LD may be variously changed depending on the design conditions of a light emitting device using the light emitting element LD or the light emitting characteristics to be secured.

In an embodiment, the light emitting device including the light emitting element LD may be used in various types of devices that require a light source. For example, light emitting elements LD may be disposed in a pixel of a display device, and the light emitting elements LD may be used as a light source for the pixel. The light emitting element LD may also be used in other types of devices that require a light source, such as a lighting device.

In an embodiment, the light emitting elements LD may be surface treated using a hydrophobic material. Accordingly, when supplying the light emitting elements LD to each light emitting area (e.g., a light emitting area of each pixel and/or sub-pixel) through an inkjet method, etc., it is possible to prevent the light emitting elements LD from being aggregated.

In an embodiment, the light emitting structure LES (also referred to as a “light emitter” or “light emitting structure”) may include semiconductor layers of different conductive types and an active layer disposed between the semiconductor layers. The light emitting structure LES may selectively further include at least one electrode layer.

In an embodiment, the multilayer insulating film MLO may surround an outer peripheral surface of the light emitting structure LES (e.g., a side surface of a rod-shaped light emitting structure LES) and may expose both ends of the light emitting structure LES (e.g., two bottom surfaces of the rod-shaped light emitting structure LES). The multilayer insulating film MLO may include at least two insulating films including different oxides. The at least two insulating films may be thin films with a thin thickness. Since the multilayer insulating film MLO has a thin thickness, it is possible to prevent or reduce the influence of the multilayer insulating film MLO on the characteristics of the light emitting structure LES.

In an embodiment, the protective film PRL may expose both ends of the light emitting structure LES (e.g., two bottom surfaces of the rod-shaped light emitting structure LES) and may be made of a single insulating film or may include two or more insulating films.

In an embodiment, the protective film PRL may be formed to stably protect the light emitting structure LES and the multilayer insulating film MLO in a process of manufacturing the light emitting element LD and/or other subsequent processes (e.g., a pixel process of forming a pixel of a display device using the light emitting element LD). For example, the protective film PRL may be formed to have a thickness sufficient to remain on a surface of the light emitting element LD, even in the case in which a portion of the thickness thereof is etched due to over-etching that may occur during a process of etching upper surfaces of the multilayer insulating film MLO and the protective film PRL during the process of manufacturing the light emitting element LD, and/or the pixel process of forming the pixel of the display device using the light emitting element LD (e.g., an etching process for forming pixel electrodes connected to both ends of the light emitting element LD). For example, the protective film PRL may be formed to have a thickness sufficient to stably surround the light emitting structure LES and the multilayer insulating film MLO, including over-etching margins that may occur in the subsequent processes.

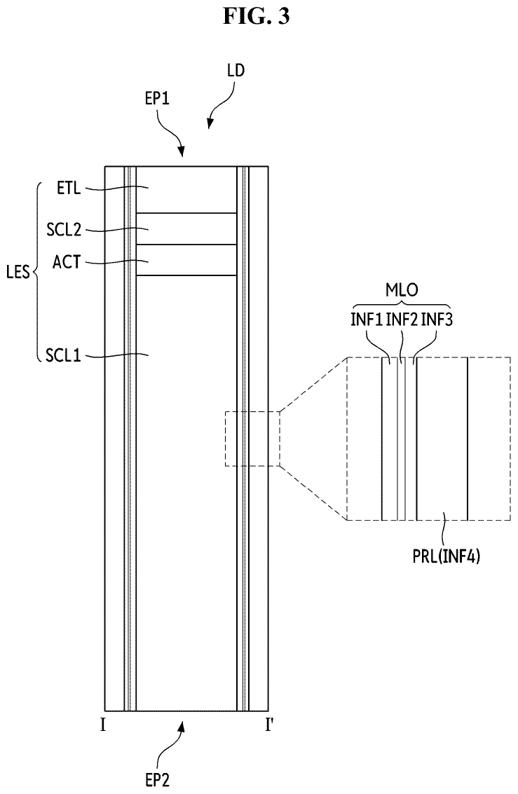

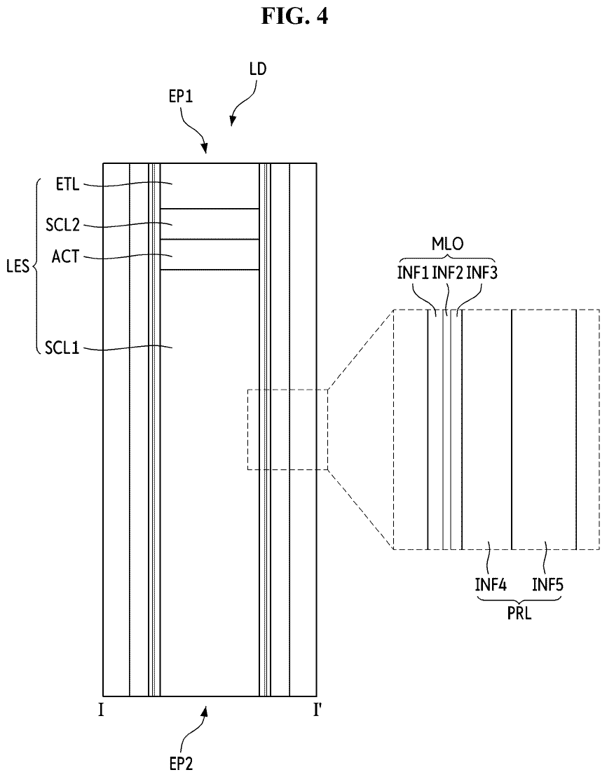

FIG. 3 is a cross-sectional view illustrating an example of the light emitting element taken along line I-I′ of FIG. 1, according to an embodiment. FIG. 4 is a cross-sectional view illustrating another example of the light emitting element taken along line I-I′ of FIG. 1, according to an embodiment.

In an embodiment and referring to FIGS. 3 and 4 in conjunction with FIGS. 1 and 2, the light emitting element LD may include a light emitting structure LES including a first semiconductor layer SCL1, an active layer ACT (also referred to as a “light emitting layer”), and a second semiconductor layer SCL2 sequentially disposed and/or stacked along one direction (e.g., a longitudinal or height direction). The light emitting structure LES may selectively further include an electrode layer ETL. The light emitting element LD may further include a multilayer insulating film MLO and a protective film PRL surrounding the light emitting structure LES.

In an embodiment, the light emitting element LD may include a first end EP1 and a second end EP2. In an embodiment, the first end EP1 and the second end EP2 may face each other. For example, the light emitting element LD may include a first end EP1 and a second end EP2 at both ends in the longitudinal direction (or height direction). The first end EP1 of the light emitting element LD may include a first bottom surface (e.g., an upper surface) of the light emitting element LD and/or a surrounding area thereof. The second end EP2 of the light emitting element LD may include a second bottom surface (e.g., a lower surface) of the light emitting element LD and/or a surrounding area thereof.

In an embodiment, the first semiconductor layer SCL1, the active layer ACT, the second semiconductor layer SCL2, and the electrode layer ETL may be sequentially disposed in a direction from the second end EP2 to the first end EP1 of the light emitting element LD. For example, the electrode layer ETL may be disposed at the first end EP1 of the light emitting element LD, and the first semiconductor layer SCL1 may be disposed at the second end EP2 of the light emitting element LD.

It is described in the embodiment of FIG. 3 that the electrode layer ETL is included in the light emitting structure LES, but the invention is not limited thereto. In an embodiment, the electrode layer ETL may be formed separately from the light emitting structure LES and may be disposed on the light emitting structure LES.

In an embodiment, the light emitting structure LES (or the light emitting element LD including the light emitting structure LES) may further include at least one other semiconductor layer (e.g., at least one other semiconductor layer disposed on and/or below the active layer ACT) and/or at least one other electrode layer (e.g., an additional electrode layer disposed around the first semiconductor layer SCL1).

In an embodiment, the first semiconductor layer SCL1 may include a semiconductor layer of a first conductive type including a dopant of the first conductive type. For example, the first semiconductor layer SCL1 may be an N-type semiconductor layer including an N-type dopant.

In an embodiment, the first semiconductor layer SCL1 may include a nitride-based semiconductor material or a phosphide-based semiconductor material. For example, the first semiconductor layer SCL1 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The first semiconductor layer SCL1 may also include other materials.

In an embodiment, the first semiconductor layer SCL1 may include an N-type dopant such as Si, Ge, or Sn. The first semiconductor layer SCL1 may also include other dopants.

In an embodiment, the active layer ACT (also referred to as “light emitting layer”) may be disposed on the first semiconductor layer SCL1 and may include a single or multiple quantum well QW structure. When the active layer ACT includes the material having the multiple quantum well structure, the active layer ACT may have a structure in which a plurality of barrier layers and well layers are alternately stacked. When a threshold voltage or more is applied to both ends of the light emitting element LD, electron-hole pairs may be recombined in the active layer ACT, and accordingly, light may be emitted from the light emitting element LD.

In an embodiment, the active layer ACT may emit light in a visible light wavelength band, for example, light in a wavelength band of approximately 400 nm to approximately 900 nm. For example, the active layer ACT may emit blue light with a peak wavelength ranging from approximately 440 nm to approximately 480 nm, green light with a peak wavelength ranging from approximately 510 nm to approximately 550 nm, or red light with a peak wavelength ranging from approximately 610 nm to approximately 650 nm. The active layer ACT may also emit light of other colors and/or wavelength bands in addition to the colors and/or wavelength bands exemplified above.

In an embodiment, the active layer ACT may include a nitride-based semiconductor material or a phosphide-based semiconductor material. For example, the active layer ACT may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. The active layer ACT may also include other materials.

In an embodiment, the second semiconductor layer SCL2 may be disposed on the active layer ACT and may include a semiconductor layer of a second conductive type including a dopant of the second conductive type. For example, the second semiconductor layer SCL2 may be a P-type semiconductor layer including a P-type dopant.

In an embodiment, the second semiconductor layer SCL2 may include a nitride-based semiconductor material or a phosphide-based semiconductor material. For example, the second semiconductor layer SCL2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The second semiconductor layer SCL2 may also include other materials.

In an embodiment, the second semiconductor layer SCL2 may include a P-type dopant such as Mg, Zn, Ca, or Ba. The second semiconductor layer SCL2 may also include other dopants.

In an embodiment, the first semiconductor layer SCL1 and the second semiconductor layer SCL2 include the same semiconductor material (e.g., the same nitride-based semiconductor material), but may include dopants of different conductive types. In another embodiment, the first semiconductor layer SCL1 and the second semiconductor layer SCL2 may include different semiconductor materials and may include dopants of different conductive types.

In an embodiment, the first semiconductor layer SCL1 and the second semiconductor layer SCL2 may have different lengths (or thicknesses) in the longitudinal direction of the light emitting element LD. As an example, the first semiconductor layer SCL1 may have a longer length (or greater thickness) than the second semiconductor layer SCL2 along the longitudinal direction of the light emitting element LD. Accordingly, the active layer ACT may be positioned closer to the first end EP1 (e.g., a P-type end) than the second end EP2 (e.g., an N-type end).

In an embodiment, the electrode layer ETL may be disposed on the second semiconductor layer SCL2 and may be an electrode that protects the second semiconductor layer SCL2 and smoothly connects the second semiconductor layer SCL2 to at least one circuit element, electrode, and/or line. For example, the electrode layer ETL may be an Ohmic contact electrode or a Schottky contact electrode.

Depending on an embodiment, the electrode layer ETL may include metal or metal oxide. As an example, the electrode layer ETL may be formed of individually or by mixing a metal such as chromium (Cr), titanium (Ti), aluminum (Al), gold (Au), nickel (Ni), or copper (Cu), oxide or alloy thereof, a transparent conductive material such as indium tin oxide (ITO), indium zinc oxide (IZO), indium tin zinc oxide (ITZO), zinc oxide (ZnO), or indium oxide (In₂O₃). The electrode layer ETL may also be formed of other materials.

In an embodiment, the electrode layer ETL may be substantially transparent. Accordingly, the light generated from the light emitting element LD may transmit through the electrode layer ETL.

In an embodiment, the multilayer insulating film MLO may surround the light emitting structure LES. For example, the multilayer insulating film MLO may surround at least the outer peripheral surfaces (e.g., side surfaces) of the first semiconductor layer SCL1, the active layer ACT, and the second semiconductor layer SCL2. In an embodiment in which the light emitting element LD further includes the electrode layer ETL, the multilayer insulating film MLO may selectively surround the electrode layer ETL. For example, the multilayer insulating film MLO may partially or entirely surround the outer peripheral surface (e.g., the side surface) of the electrode layer ETL, or may not surround the electrode layer ETL.

In an embodiment, the multilayer insulating film MLO may expose the electrode layer ETL and the first semiconductor layer SCL1 at the first end EP1 and the second end EP2 of the light emitting element LD, respectively. For example, the multilayer insulating film MLO may not be provided on the two bottom surfaces (e.g., the upper and lower surfaces of the light emitting element LD) corresponding to the first and second ends EP1 and EP2 of the light emitting element LD. Accordingly, an electrical signal (e.g., a driving signal and/or a power voltage) may be applied to the light emitting element LD through the first end EP1 and the second end EP2 of the light emitting element LD.

In an embodiment, the multilayer insulating film MLO may be provided on the surface of the light emitting structure LES to ensure electrical stability of the light emitting element LD. In addition, the multilayer insulating film MLO may slow down the deterioration of the light emitting element LD and increase reliability thereof by blocking or reducing oxygen from flowing into the light emitting structure LES. For example, the multilayer insulating film MLO may include oxygen vacancies formed at an interface of different insulating films. The multilayer insulating film MLO may block or reduce oxygen from flowing into the light emitting structure LES by capturing oxygen through the oxygen vacancies.

In an embodiment, the multilayer insulating film MLO may include a first insulating film INF1, a second insulating film INF2, and a third insulating film INF3.

In an embodiment, the first insulating film INF1 may surround the light emitting structure LES. For example, the first insulating film INF1 may surround the outer peripheral surfaces (e.g., side surfaces) of the first semiconductor layer SCL1, the active layer ACT, and the second semiconductor layer SCL2, and may be in direction contact therewith. In an embodiment, the first insulating film INF1 may further surround at least a portion of the electrode layer ETL (e.g., at least a portion of the side surface).

In an embodiment, the second insulating film INF2 may surround the first insulating film INF1. For example, the second insulating film INF2 may surround an outer peripheral surface (e.g., side surface) of the first insulating film INF1 and may be in direct contact with the outer peripheral surface of the first insulating film INF1.

In an embodiment, the third insulating film INF3 may surround the second insulating film INF2. For example, the third insulating film INF3 may surround an outer peripheral surface (e.g., side surface) of the second insulating film INF2 and may be in direct contact with the outer peripheral surface of the second insulating film INF2.

In an embodiment, the first insulating film INF1, the second insulating film INF2, and the third insulating film INF3 may include an oxide that may reduce or minimize defects in the light emitting element LD while generating enough oxygen vacancies to improve deterioration of the light emitting element LD at the interfaces thereof.

In an embodiment, the first insulating film INF1 may include any one selected from the group consisting of zirconium oxide (ZrO₂), hafnium oxide (HfO₂), lanthanum oxide (La₂O₃), tantalum oxide (Ta₂O₅), yttrium oxide (Y₂O₃), niobium oxide (Nb₂O₅), and titanium oxide (TiO₂). The first insulating film INF1 may include a material with similar crystallinity to the material of the first and second semiconductor layers SCL1 and SCL2, for example, GaN. In an embodiment, the first insulating film INF1 may include zirconium oxide (ZrO₂) or hafnium oxide (HfO₂) and may be formed with excellent crystallinity on the surfaces of the first and second semiconductor layers SCL1 and SCL2. A thickness of the first insulating film INF1 may be about 10 nm or less, for example, about 1 nm to about 3 nm.

In an embodiment, the second insulating film INF2 may include at least one of (Ta₂O₅), yttrium oxide (Y₂O₃), niobium oxide (Nb₂O₅), aluminum oxide (Al₂O₃), cerium oxide (Ce₂O₃), ytterbium oxide (Yb₂O₃), and titanium oxide (TiO₂). The second insulating film INF2 may serve as a barrier film that prevents damage generated during deposition of the protective film PRL from reaching the surfaces of the semiconductor layers SCL1 and SCL2 and the active layer ACT. In an embodiment, the second insulating film INF2 may include aluminum oxide (Al₂O₃). A thickness of the second insulating film INF2 may be about 10 nm or less, for example, about 1 nm to about 3 nm.

In an embodiment, the third insulating film INF3 may include at least one of zirconium oxide (ZrO₂), hafnium oxide (HfO₂), lanthanum oxide (La₂O₃), tantalum oxide (Ta₂O₅), yttrium oxide (Y₂O₃), niobium oxide (Nb₂O₅), and titanium oxide (TiO₂). The third insulating film INF3 may include the same material as the first insulating film INF1 or may include a different material from the first insulating film INF1. In an embodiment, the third insulating film INF3 may include zirconium oxide (ZrO₂) or hafnium oxide (HfO₂). A thickness of the third insulating film INF3 may be about 10 nm or less, for example, about 1 nm to about 3 nm.

In an embodiment, the first insulating film INF1, the second insulating film INF2, and the third insulating film INF3 may be formed as thin films that are enough to reduce or minimize an influence on the light emitting structure LES. For example, the sum of the thicknesses of the first insulating film INF1, the second insulating film INF2, and the third insulating film INF3 may be about 10 nm or less. In addition, the first insulating film INF1, the second insulating film INF2, and the third insulating film INF3 may be formed to have a limited thickness to reduce or minimize defects of the light emitting element LD while smoothly inducing an interface reaction that generates oxygen vacancies sufficient to improve the deterioration of the light emitting element LD at the interfaces of the insulating films.

For example, in an embodiment, the second insulating film INF2 may be formed to have a thickness of about 3 nm or less to smoothly induce the interface reaction, but is not limited thereto. The first insulating film INF1 may be formed to have a greater thickness than the second insulating film INF2 to prevent defects from occurring in an area that is too close to the light emitting structure LES, and may be formed to have a limited thickness so as to reduce or minimize the impact on the light emitting structure LES. For example, the second insulating film INF2 may be formed to have a thickness of about 3 nm or less (e.g., a thickness in the range of approximately 2 nm to approximately 3 nm), but is not limited thereto. The third insulating film INF3 may be formed to have a thickness greater than or equal to the thickness of the second insulating film INF2 so that the interface reaction may occur relatively uniformly at the interface between the first insulating film INF1 and the second insulating film INF2 and the interface between the second insulating film INF2 and the third insulating film INF3. For example, the third insulating film INF3 may be formed to have a thickness of about 3 nm or less, but is not limited thereto. Accordingly, the reliability of the light emitting element LD may be increased by reducing or minimizing the defects of the light emitting element LD and improving deterioration characteristics of the light emitting element LD.

In an embodiment, the protective film PRL may surround the multilayer insulating film MLO. For example, the protective film PRL may surround the third insulating film INF3 and expose the first end EP1 and the second end EP2 of the light emitting element LD.

In an embodiment, the protective film PRL may include at least one insulating film. For example, the protective film PRL may surround a fourth insulating film INF4.

In an embodiment, the fourth insulating film INF4 may surround the multilayer insulating film MLO. For example, the fourth insulating film INF4 may surround an outer peripheral surface (e.g., side surface) of the third insulating film INF3 and may be in direction contact with the outer peripheral surface of the third insulating film INF3.

In an embodiment, the protective film PRL may be formed of only a single layer of the fourth insulating film INF4, as in the embodiment of FIG. 3. The fourth insulating film INF4 may be formed of a material and/or thickness that may stably protect the light emitting structure LES and the multilayer insulating film MLO in the process of manufacturing the light emitting element LD and/or other subsequent processes (e.g., an etching process included in the pixel process of the display device using the light emitting element LD). For example, the fourth insulating film INF4 may include at least one of (Ta₂O₅), yttrium oxide (Y₂O₃), niobium oxide (Nb₂O₅), silicon oxide (SiO₂), silicon nitride (SiNx), silicon oxynitride (SiOxNy), and titanium oxide (TiO₂).

In an embodiment, a thickness of the fourth insulating film INF4 may be greater than the sum of the thicknesses of the first insulating film INF1, the second insulating film INF2, and the third insulating film INF3. As an example, the fourth insulating film INF4 includes silicon oxide (SiO₂) and may have a thickness ranging from about 10 nm to about 200 nm, but is not limited thereto.

In another embodiment, the protective film PRL may be made of a double layer of insulating films including a fourth insulating film INF4 and a fifth insulating film INF5, as in the embodiment shown in FIG. 4.

In an embodiment, the fifth insulating film INF5 may surround the fourth insulating film INF4. For example, the fifth insulating film INF5 may surround an outer peripheral surface (e.g., side surface) of the fourth insulating film INF4 and may be in direction contact with the outer peripheral surface of the fourth insulating film INF4.

In an embodiment, the fifth insulating film INF5 may protect the light emitting structure LES and the multilayer insulating film MLO together with the fourth insulating film INF4. For example, the fifth insulating film INF5 may be formed of a material and/or thickness that may stably protect the light emitting structure LES and the multilayer insulating film MLO in the process of manufacturing the light emitting element LD and/or other subsequent processes (e.g., an etching process for forming the pixel process on the light emitting element LD). For example, the fifth insulating film INF5 may include at least one of zirconium oxide (ZrO₂), hafnium oxide (HfO₂), lanthanum oxide (La₂O₃), tantalum oxide (Ta₂O₅), yttrium oxide (Y₂O₃), niobium oxide (Nb₂O₅), silicon oxide (SiO₂), silicon nitride (SiNx), silicon oxynitride (SiOxNy), and titanium oxide (TiO₂).

In an embodiment, the fifth insulating film INF5 may have a greater thickness than the fourth insulating film INF4. As an example, the fifth insulating film INF5 includes aluminum oxide (Al₂O₃) and may have a thickness ranging from about 10 nm to about 200 nm, but is not limited thereto.

The structure, material, and/or thickness of the protective film PRL are not limited to the above-described embodiments. For example, in an embodiment, the protective film PRL may be made of three or more layers of insulating films that further include the fourth insulating film INF4 and the fifth insulating film INF5, and one or more additional insulating films.

In an embodiment, when the protective film PRL is formed of at least two insulating films including the fourth insulating film INF4 and the fifth insulating film INF5, the thickness of each insulating film constituting the protective film PRL may be reduced. Accordingly, the process time for forming the protective film PRL may be shortened and the process efficiency may be increased.

The light emitting element LD, according to an embodiment, may have improved reliability and excellent luminance maintenance rate compared to initial luminance. In an embodiment, a diameter of the light emitting structure LES of the light emitting element LD may range from about 0.5 μm to about 10 μm. For example, the diameters of the first semiconductor layer SCL1, the active layer ACT, and the second semiconductor layer SCL2 may range from about 0.5 μm to about 10 μm. In another embodiment, the diameter of the light emitting structure LES, for example, the diameters of the first semiconductor layer SCL1, the active layer ACT, and the second semiconductor layer SCL2 may range from about 0.5 μm to about 6 μm.

According to an embodiment, the first insulating film INF1 of the multilayer insulating film MLO may include a small amount of impurities to improve the reliability of the light emitting element LD. Here, the impurity may be carbon. For example, a carbon content in the first insulating film INF1 may be about 3% to about 30%. Here, the carbon content is in atomic percentage (atomic %). The first insulating film INF1, which is an insulating film in direct contact with the light emitting structure LES, may be an insulating film that may directly affect the light emitting structure LES. If the content of carbon, which an impurity in the first insulating film INF1, is high, a film quality may deteriorate and a barrier function may deteriorate. In an embodiment, the efficiency and reliability of the light emitting element LD may be improved by forming the carbon content in the first insulating film INF1 to be about 3% to about 30%.

In another embodiment, the carbon content in each of the insulating films INF1, INF2, and INF3 of the multilayer insulating film MLO and the fourth insulating film INF4 and/or the fifth insulating film INF5 of the protective film PRL may be about 3% to about 30%. Each of the insulating films INF1, INF2, and INF3 of the multilayer insulating film MLO and the fourth insulating film INF4 and/or the fifth insulating film INF5 of the protective film PRL is an insulating film that performs a barrier function to protect the light emitting element LD, and may improve the efficiency and reliability of the light emitting element LD by having a low content of carbon, which is an impurity in the film.

According to still another embodiment, the carbon content in the first insulating film INF1 may be greater than the carbon content in the insulating film disposed at the outermost portion. That is, the carbon content in the insulating film forming the outermost portion may be smaller than the carbon content in the first insulating film INF1. In the embodiment of FIG. 3, the carbon content in the first insulating film INF1 may be greater than the carbon content in the fourth insulating film INF4. In the embodiment of FIG. 4, the carbon content in the first insulating film INF1 may be greater than the carbon content in the fifth insulating film INF5.

In an embodiment, since the insulating film (e.g., the fourth insulating film INF4 or the fifth insulating film INF5) disposed at the outermost portion primarily functions to protect the light emitting structure LES at the outermost portion of the light emitting element LD, the quality of the insulating film disposed at the outermost portion needs to be excellent. In an embodiment, by forming the carbon content in the insulating film (e.g., the fourth insulating film INF4 or the fifth insulating film INF5) disposed at the outermost portion to be smaller than the carbon content in the first insulating film INF1, the efficiency and reliability of the light emitting element LD may be improved.

In an embodiment, the first insulating film INF1 may have a relatively dense film density by having the carbon content in the range of about 3% to about 30%. For example, when the first insulating film INF1 includes zirconium oxide (ZrO₂), the film density may be about 5 or less, preferably about 3 to about 5. When the first insulating film INF1 includes hafnium oxide (HfO₂), the film density may be about 8 or less, preferably about 6 to about 8. When the first insulating film INF1 includes lanthanum oxide (La₂O₃), the film density may be about 6 or less, preferably about 4 to about 6. When the first insulating film INF1 includes tantalum oxide (Ta₂O₅), the film density may be about 8 or less, preferably about 6 to about 8. When the first insulating film INF1 includes yttrium oxide (Y₂O₃), the film density may be about 5 or less, preferably about 3 to about 5. When the first insulating film INF1 includes niobium oxide (Nb₂O₅), the film density may be about 4.5 or less, preferably about 2.5 to about 4.5. When the first insulating film INF1 includes titanium oxide (TiO₂), the film density may be about 4 or less, preferably about 2 to about 4.

In an embodiment, the efficiency and reliability of the light emitting element LD may be improved by forming the film density of the first insulating film INF1 in the above-mentioned ranges.

Table 1 below shows an embodiment where the atomic ratios in the films measured using a mass spectrometer after depositing zirconium oxide (ZrO₂) thin films of about 3 nm on a glass substrate. Zirconium oxide (ZrO₂) thin films were manufactured using different precursors 1 and 2, respectively. Here, the precursor 1 is a Zr precursor and the number of carbons directly bonded to Zr is 1, and the precursor 2 is a Zr precursor and the number of carbons directly bonded to Zr is 0.

TABLE 1

Atomic Ratio (Atomic %)

| | Carbon | Nitrogen | Oxygen | Zirconium |
|---|---|---|---|---|
| | (C) | (N): | (O) | (Zr) |
| Precursor 1 | 8.0 | 0 | 60.0 | 32.0 |
| Precursor 2 | 5.8 | 0 | 61.3 | 32.9 |

In an embodiment and referring to Table 1, the zirconium oxide (ZrO₂) thin film deposited using the zirconium precursor 1 showed a carbon atomic ratio of about 8%, and the zirconium oxide (ZrO₂) thin film deposited using the zirconium precursor 2 showed a carbon atomic ratio of about 5.8%.

Through this, it was confirmed that the first insulating film INF1 including zirconium oxide (ZrO₂) could be manufactured with a carbon content of about 3% to about 30%.

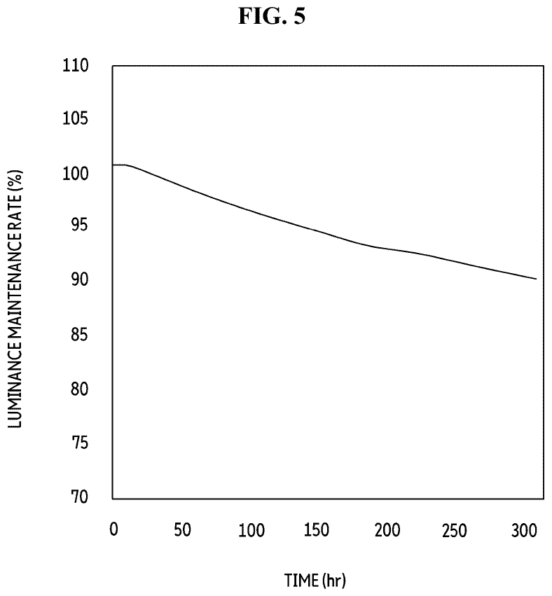

FIG. 5 is a graph illustrating a luminance maintenance rate of the light emitting element over time, according to an embodiment. For example, FIG. 5 illustrates the luminance maintenance rate of the light emitting element LD including the multilayer insulating film MLO and the fourth insulating film INF4 by forming the zirconium oxide (ZrO₂) thin film manufactured using the precursor 2 in Table 1 as the first insulating film INF1 of the light emitting element LD. The luminance maintenance rate of the light emitting element LD was calculated through a change in luminance of light emitted from the light emitting element LD by applying a driving current signal. The active layer ACT of the light emitting element LD emits blue light with a peak wavelength in the range of about 440 to about 480 nm, and was formed to have a diameter in the range of about 0.5 μm to about 6 μm. Here, the driving current (driving current density) was applied at about 50 A/cm² and continuously driven for about 300 hours.

In an embodiment and referring to FIG. 5 in addition to FIGS. 1 to 5, the light emitting element LD including the first insulating film INF1 including zirconium oxide (ZrO₂) with a carbon content of about 5.8% may exhibit characteristics in which the luminance maintenance rate compared to the initial luminance is maintained to be high even over time. It was confirmed that more than about 90% of the initial luminance of about 100% was maintained when the driving current of about 50 A/cm² or more was applied and continuously driven for about 300 hours.

As described above, the light emitting element LD, according to an embodiment, may improve deterioration characteristics thereof and reliability thereof by adjusting the carbon content in the first insulating film INF1.

Hereinafter, a method for manufacturing a light emitting element, according to an embodiment, will be described.

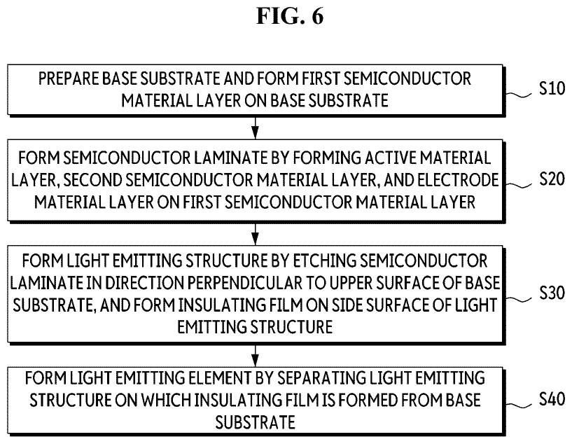

FIG. 6 is a flowchart illustrating a method for manufacturing a light emitting element, according to an embodiment.

Referring to FIG. 6, a method for manufacturing a light emitting element, according to an embodiment, may include preparing a base substrate and forming a first semiconductor material layer on the base substrate (S10), forming a semiconductor laminate by forming an active material layer, a second semiconductor material layer, and an electrode material layer on the first semiconductor material layer (S20), forming a light emitting structure by etching the semiconductor laminate in a direction perpendicular to an upper surface of the base substrate, and forming an insulating film on a side surface of the light emitting structure (S30), and forming a light emitting element by separating the light emitting structure on which the insulating film is formed from the base substrate (S40).

In an embodiment, the method for manufacturing the light emitting element LD may include forming a semiconductor laminate on the base substrate and then etching and separating the semiconductor laminate. In the process of forming the insulating film, the insulating film composed of a plurality of layers is formed, so that side defects of the etched light emitting structure may be compensated. Hereinafter, the method for manufacturing the light emitting element will be described in detail with further reference to other drawings.

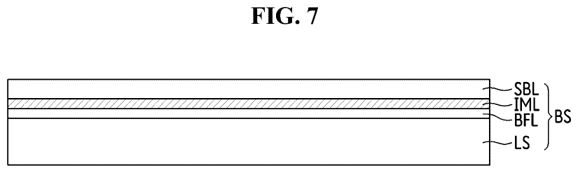

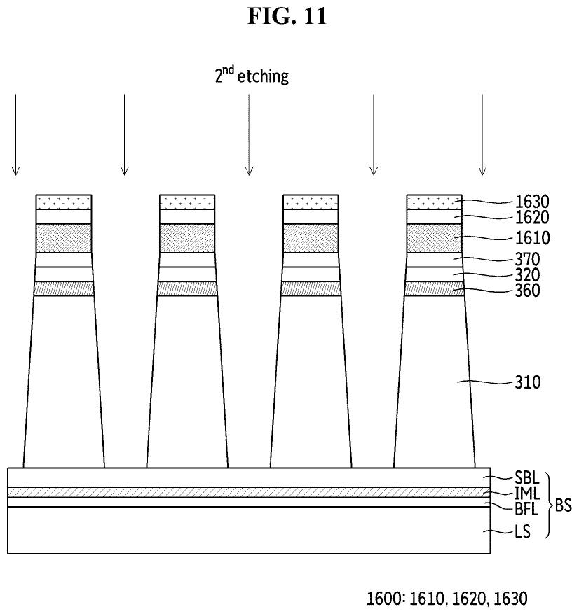

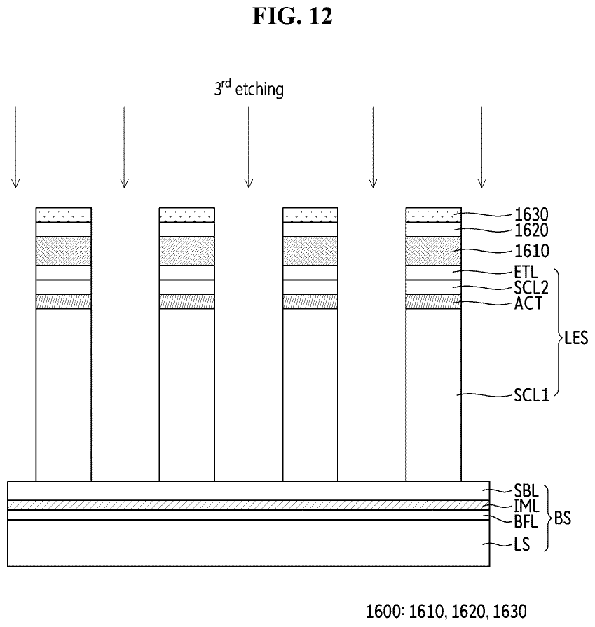

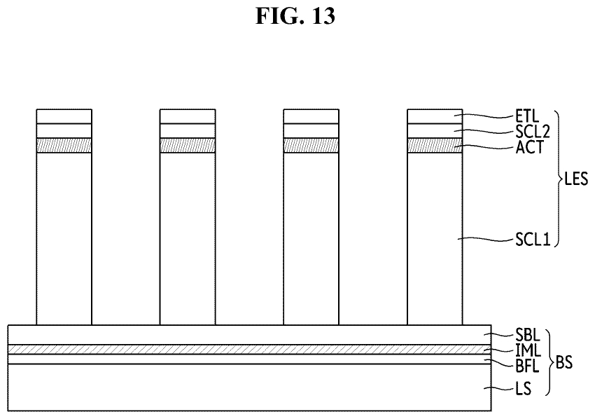

FIGS. 7 to 16 are cross-sectional views sequentially illustrating a process of manufacturing a light emitting element, according to an embodiment.

In an embodiment and referring to FIG. 7, a base substrate BS on which a semiconductor laminate is formed is prepared and may include a lower substrate LS, a buffer material layer BFL, an intermediate layer IML, and a semiconductor base layer SBL.

In an embodiment, the lower substrate LS may include a sapphire (Al₂O₃) substrate and a transparent substrate such as glass. However, the lower substrate LS is not limited thereto, and may be formed as a conductive substrate such as GaN, SiC, ZnO, Si, GaP, and GaAs. A thickness of the lower substrate LS is not particularly limited, but the lower substrate LS may have a thickness in the range of about 400 μm to about 1500 μm as an example.

In an embodiment, the buffer material layer BFL may be disposed to reduce a difference in lattice constant between a first semiconductor material layer 310 formed thereon and the lower substrate LS. In an embodiment, the buffer material layer BFL may be made of at least one of InAlGaN, GaN, AlGaN, InGaN, AlN, and InN, but is not limited thereto.

In an embodiment, the intermediate layer IML may be disposed on the buffer material layer BFL to reduce a defect density of the semiconductor layer disposed thereon. As the intermediate layer IML is inserted into the base substrate BS in the process of manufacturing the light emitting element LD, the defect density of semiconductor material layers formed through an epitaxial growth process may be reduced, and the defect density of the finally manufactured light emitting element LD may also be reduced. Through this, factors that lower an external quantum efficiency of the light emitting element LD may be reduced. In an embodiment, the intermediate layer IML may include AlN or SiNx.

In an embodiment, the semiconductor base layer SBL may provide a seed crystal on which the semiconductor laminate may be grown. As an example, the semiconductor base layer SBL may include an undoped semiconductor. The semiconductor base layer SBL may include substantially the same material as the first semiconductor material layer 310, and the material may be an n-type or p-type undoped material or doping concentration thereof may be lower than that of the first semiconductor material layer 310. For example, the semiconductor base layer SBL may include undoped GaN.

In an embodiment, in the method for manufacturing the light emitting element LD, the intermediate layer IML may be inserted into the base substrate BS, and the defect density of the semiconductor base layer SBL may be low. As an example, the defect density of the semiconductor base layer SBL including the undoped semiconductor may be about 1.0*10⁸/cm² or less, or about 6*10⁷/cm² or less.

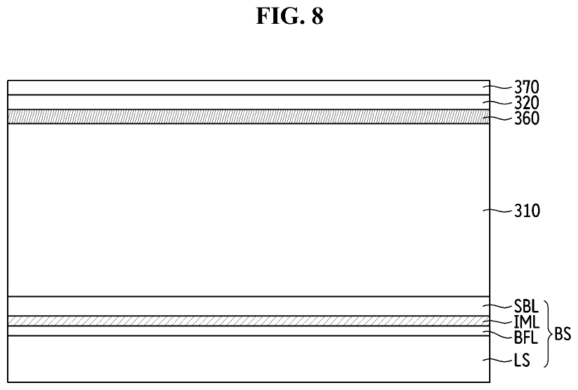

Next, in an embodiment and referring to FIG. 8, a first semiconductor material layer 310, an active material layer 360, a second semiconductor material layer 320, and an electrode material layer 370 are sequentially formed on the semiconductor base layer SBL of the base substrate BS.

In an embodiment, a plurality of semiconductor material layers may be formed by growing a seed crystal using an epitaxial method. Here, a method of forming the semiconductor material layers may be electron beam deposition, physical vapor deposition (PVD), chemical vapor deposition (CVD), plasma laser deposition (PLD), dual-type thermal evaporation, sputtering, metal organic chemical vapor deposition (MOCVD), or the like, and preferably, the semiconductor material layers may be formed by metal-organic chemical vapor deposition (MOCVD). However, the invention is not limited thereto.

In an embodiment, a precursor material for forming the semiconductor material layers is not particularly limited within a range that may be generally selected for forming a target material. As an example, the precursor material may include a metal precursor including an alkyl group such as a methyl group or an ethyl group. For example, like the light emitting element LD in the embodiment in which the first semiconductor layer SCL1, the second semiconductor layer SCL2, and the active layer ACT include any one of AlGaInN, GaN, AlGaN, InGaN, AlN, and InN, the metal precursor may be trimethyl gallium (Ga(CH₃)₃), and may be a compound such as trimethyl aluminum (Al(CH₃)₃) or triethyl phosphate ((C₂H₅)₃PO₄). However, the invention is not limited thereto. The plurality of semiconductor material layers may be formed through a deposition process using the metal precursor and non-metal precursor.

In an embodiment, the layers disposed on the base substrate BS may correspond to the semiconductor layers SCL1 and SCL2, the active layer ACT, and the electrode layer ETL of the light emitting element LD, respectively. For example, the first semiconductor material layer 310 may correspond to the first semiconductor layer SCL1, and the active material layer 360 and the second semiconductor material layer 320 may correspond to the active layer ACT and the second semiconductor layer SCL2, respectively. That is, each of the material layers may include the same material as each of the semiconductor layers SCL1 and SCL2 and the active layer ACT of the light emitting element LD.

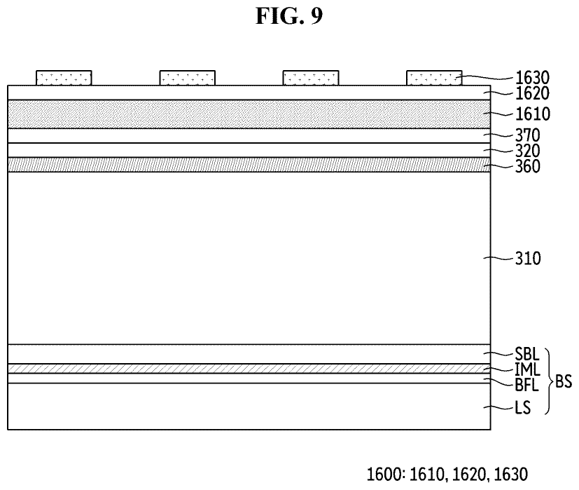

Next, in an embodiment and referring to FIGS. 9 to 13, light emitting structures spaced apart from each other are formed by etching the semiconductor material layers 310 and 320, the active material layer 360, and the electrode material layer 370. According to an embodiment, the step of etching the semiconductor material layers 310 and 320, the active material layer 360, and the electrode material layer 370 may include a step (first etching) of forming a mask layer on the electrode material layer 370, and a plurality of etching processes (second etching and third etching) of etching the semiconductor material layers 310 and 320 along the mask layer.

First, in an embodiment and as illustrated in FIG. 9, a plurality of mask layers 1610, 1620, and 1630 are formed on the electrode material layer 370. The plurality of mask layers 1610, 1620, and 1630 may include a first insulating mask layer 1610 and a second insulating mask layer 1620 disposed on the electrode material layer 370, and mask patterns 1630 disposed on the second insulating mask layer 1620. The first insulating mask layer 1610 and the second insulating mask layer 1620 may be etched along a space where the mask patterns 1630 are spaced apart from each other in a subsequent process. The semiconductor material layers 310, 320, 360, and 370 may be etched along the insulating mask layers 1610 and 1620 and the space where the mask patterns 1630 are spaced apart from each other. In an embodiment, the mask patterns 1630 may have the same diameter or width. A portion of the semiconductor material layers 310 and 320 that overlaps the portion where the mask pattern 1630 is disposed and is not etched may form the light emitting structure constituting the light emitting element LD. In addition, the diameter of the mask pattern 1630 may be substantially the same as the diameter of the light emitting element LD. As the mask patterns 1630 have the same diameter or width, the light emitting elements LD may also have substantially the same diameter.

In an embodiment, the first insulating mask layer 1610 and the second insulating mask layer 1620 may include an insulating material, and the mask pattern 1630 may include a metal material. For example, the insulating mask layers 1610 and 1620 may be made of silicon oxide (SiOₓ), silicon nitride (SiNₓ), and silicon oxynitride (SiOₓN_{y}), respectively. The mask pattern 1630 may include a metal such as chromium (Cr), but is not limited thereto.

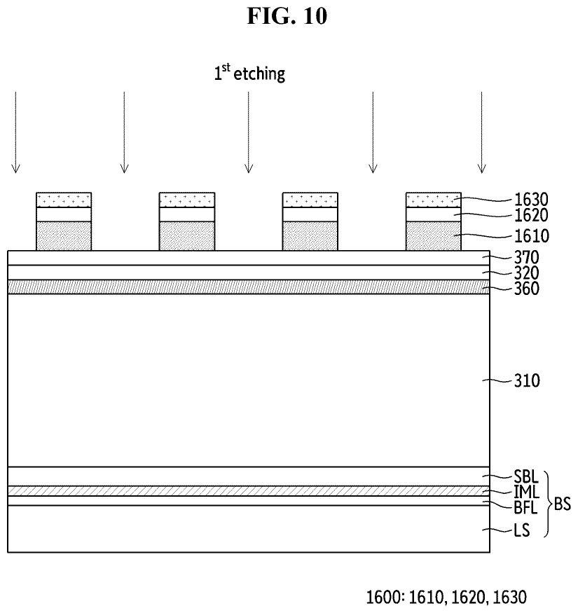

Next, in an embodiment and as illustrated in FIGS. 10 to 13, a first etching process of etching the insulating mask layers 1610 and 1620 along the mask pattern 1630, and second and third etching processes for etching the semiconductor material layers 310 and 320 along the etched insulating mask layers 1610 and 1620 are performed. Each etching process may be performed in a direction that is directed perpendicular to the upper surface of the base substrate BS.

In an embodiment, the etching process may be a dry etching method, a wet etching method, a reactive ion etching (RIE) method, an inductively coupled plasma reactive ion etching (ICP-RIE) method, or the like. Since anisotropic etching is possible in the dry etching method, the dry etching method may be suitable for vertical etching. When the above-described etching method is used, an etching etchant may be Cl₂ or O₂. However, the invention is not limited thereto.

In an embodiment, the first etching process may be performed as a process of etching the insulating mask layers 1610 and 1620 exposed in areas where the mask patterns 1630 are spaced apart from each other. The insulating mask layers 1610 and 1620 may be formed in an etched form along the mask pattern 1630 and may function as a mask for etching the lower semiconductor material layers.

Next, in an embodiment, the semiconductor material layers are etched using the mask pattern 1630 and the etched insulating mask layers 1610 and 1620 as masks. The process of etching the semiconductor material layers may include a second etching process that is performed as a dry etching process, and a third etching process, which is a wet etching process, performed after the second etching process.

In the second etching process, the semiconductor material layers may be etched in the direction perpendicular to the upper surface of the base substrate BS to form light emitting structures spaced apart from each other, according to an embodiment. However, in the present etching process, side surfaces of the light emitting structures may have an inclined shape rather than being directed perpendicular to the upper surface of the base substrate BS. A third etching process may be performed so that the side surfaces of the light emitting structures are formed to be directed perpendicular to the base substrate BS. The second etching process and the third etching process may be performed as a dry etching process and a wet etching process, respectively, and the light emitting structures spaced apart from each other may be formed on the base substrate BS by the present etching process. The light emitting structures may each include a first semiconductor material layer 310, an active material layer 360, a second semiconductor material layer 320, and an electrode material layer 370.

However, in an embodiment and as described above, the side surfaces or surfaces of the light emitting structures LES formed through the etching process may be severely damaged. Such surface damage may cause an abnormal recombination of light by light emitting element LD within the semiconductor layer, and may cause the light efficiency and electrical characteristics of the light emitting element LD to deteriorate. To minimize such performance degradation, the light emitting element LD may include a multilayer insulating film MLO and a protective film PRL surrounding at least the side surfaces of the semiconductor layers SCL1, SCL2, and ACT.

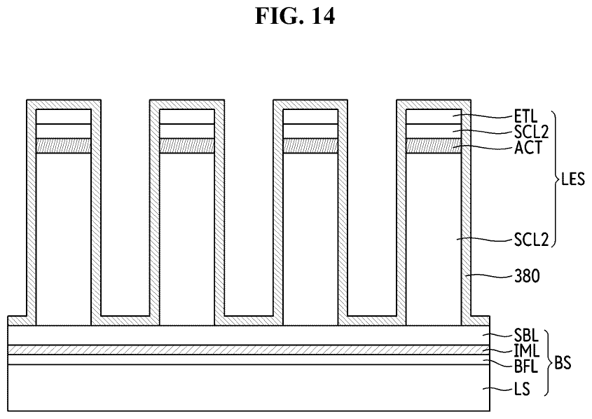

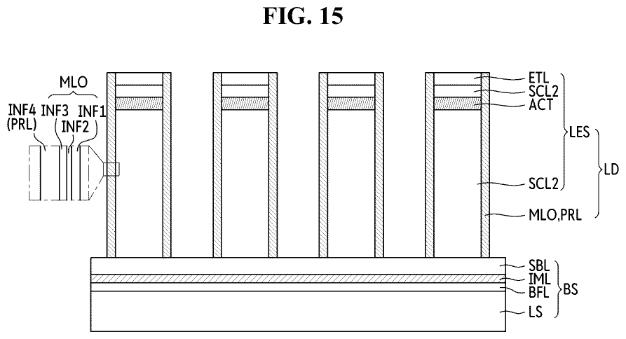

Next, in an embodiment and referring to FIGS. 14 and 15, a multilayer insulating film MLO and a protective film PRL partially surrounding the side surface of the light emitting structure LES are formed. The multilayer insulating film MLO and the protective film PRL may be formed by a process of forming a multilayer insulating material layer 380 to surround an outer surface of the light emitting structure LES, and then partially removing the multilayer insulating material layer 380 so that an upper surface of a semiconductor rod is exposed.

According to an embodiment, the insulating material layer 380 may be formed through a chemical vapor deposition (CVD) or atomic layer deposition (ALD) process. The chemical vapor deposition (CVD) or atomic layer deposition (ALD) process may be performed as a deposition method using a metal precursor material, a reactant, and a reactive gas of the material constituting the multilayer insulating material layer 380. The multilayer insulating material layer 380 may be formed by sequentially stacking the first to third insulating films INF1, INF2, and INF3. The protective film PRL may be sequentially formed on the third insulating film INF3, including the fourth insulating film INF4.

According to an embodiment, in the process of forming the first insulating film INF1, a metal precursor material having carbons of one or less directly bonded to the metal among the metal precursor materials, for example, having carbons of 1 or 0 directly bonded to the metal may be used. Examples of the metal precursor materials having carbons of 1 or 0 directly bonded to the metal may include the precursor 1 and the precursor 2 used in Table 1 above. When using the metal precursor material having carbons of 1 or 0 directly bonded to the metal, the carbon content in the deposited first insulating film INF1 may be about 3% to about 30%. That is, the reliability of the light emitting element LD may be improved by reducing the carbon content in the first insulating film INF1 using the metal precursor material having carbons of 1 or 0 directly bonded to the metal to reduce the impurities in the first insulating film INF1.

In an embodiment, as another method for reducing the impurities in the first insulating film INF1, the reactant added together with the metal precursor may be used as O₂ or O₃ gas which have a high degree of oxidation and which may easily be substituted for carbon directly bonded to the metal in the metal precursor. That is, by using the O₂ or O₃ gas as the reactant, the carbon content in the first insulating film INF1 may be reduced. The carbon content of at least one of the insulating films INF1, INF2, INF3, and INF4 may be reduced using the above-described methods.

In an embodiment, the multilayer insulating material layer 380 may also be formed on the side and upper surfaces of the light emitting structure LES and on the base substrate BS exposed in areas where the light emitting structures LES are spaced apart from each other. In order to partially remove the multilayer insulating material layer 380 disposed on the upper surfaces of the light emitting structures LES and the portions where the light emitting structures LES are spaced apart from each other, a process such as dry etching, which is anisotropic etching, or etch-back may be performed. In some embodiments, the upper surface of the multilayer insulating material layer 380 may be removed to expose the electrode layer ETL. When a portion of the multilayer insulating material layer 380 is removed, the multilayer insulating film MLO and the protective film PRL surrounding the side surfaces of the semiconductor layers in the light emitting element LD may be formed.

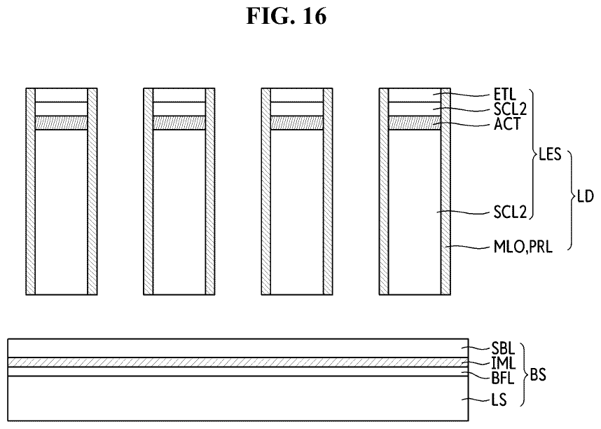

Finally, in an embodiment and as illustrated in FIG. 16, the light emitting element LD in which the multilayer insulating film MLO and the protective film PRL are formed is separated from the base substrate BS.

Hereinafter, a display device including the light emitting element LD, according to an embodiment, and electronic devices applied to the display device will be described.

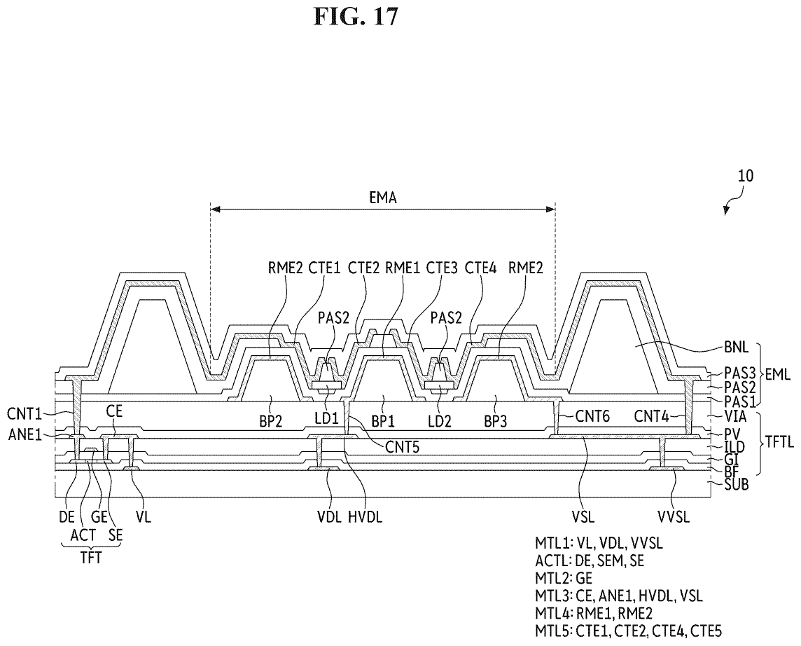

FIG. 17 is a cross-sectional view of a display device, according to an embodiment.

Referring to FIG. 17, the display device 10, according to an embodiment, may include a substrate SUB, a thin film transistor layer TFTL, and a light emitting element layer EML. The display device 10 may emit light by including a light emitting element LD disposed on the light emitting element layer EML.

In an embodiment, the substrate SUB may be a base substrate or a base member. The substrate SUB may be a flexible substrate that may be bent, folded, rolled, or the like. For example, the substrate SUB may include a glass material or a metal material, but is not limited thereto. As another example, the substrate SUB may include a polymer resin such as polyimide (PI).

In an embodiment, the thin film transistor layer TFTL may be disposed on the substrate SUB and may include a first metal layer MTL1, a buffer layer BF, an active layer ACTL, a gate insulating layer GI, a second metal layer MTL2, an interlayer insulating layer ILD, a third metal layer MTL3, a protective layer PV, and a via layer VIA.

In an embodiment, the first metal layer MTL1 may be disposed on the substrate SUB and may include a voltage line VL, a first voltage line VDL, and a vertical voltage line VVSL, where the voltage line VL may be a first voltage line VDL, an initialization voltage line VIL, or a data line DL.

In an embodiment, the buffer layer BF may be disposed on the first metal layer MTL1. For example, the buffer layer BF may include an inorganic film capable of preventing permeation of air or moisture. For example, the buffer layer BF may include a plurality of inorganic films that are alternately stacked.

In an embodiment, the active layer ACTL may be disposed on the buffer layer BF and may include a drain electrode DE, a semiconductor area SEM, and a source electrode SE of the thin film transistor TFT. For example, the semiconductor area SEM of the thin film transistor TFT may include low temperature polycrystalline silicon (LTPS). The thin film transistor TFT including the low temperature polycrystalline silicon may have high electron mobility and excellent turn-on characteristics. As another example, the semiconductor area SEM of the thin film transistor TFT may include oxide. The thin film transistor TFT including the oxide may have excellent leakage current characteristics and may be driven at low frequencies, thereby reducing power consumption.

In an embodiment, the gate insulating layer GI may be disposed on the active layer ACTL, where the gate insulating layer GI may insulate the active layer ACTL and the second metal layer MTL2 from each other.

In an embodiment, the second metal layer MTL2 may be disposed on the gate insulating layer GI and may include a gate electrode GE of the thin film transistor TFT. The gate electrode GE of the thin film transistor TFT may overlap the semiconductor area SEM.

In an embodiment, the interlayer insulating layer ILD may be disposed on the second metal layer MTL2 and may insulate the second metal layer MTL2 and the third metal layer MTL3 from each other.

In an embodiment, the third metal layer MTL3 may be disposed on the interlayer insulating layer ILD. The third metal layer MTL3 may include a connection electrode CE, a first anode connection electrode ANE1, a horizontal voltage line HVDL, and a second voltage line VSL. The connection electrode CE may electrically connect the voltage line VL and the source electrode SE of the thin film transistor TFT. The first anode connection electrode ANE1 may electrically connect the drain electrode DE of the thin film transistor TFT and a first contact electrode CTE1. The horizontal voltage line HVDL may electrically connect the first voltage line VDL and a first electrode RME1. The second voltage line VSL may electrically connect the vertical voltage line VVSL and a second electrode RME2, and may electrically connect the vertical voltage line VVSL and a fifth contact electrode CTE5.

In an embodiment, the protective layer PV may be disposed on the third metal layer MTL3. The protective layer PV may be disposed on a plurality of thin film transistors TFT to protect a pixel circuit of pixels.

In an embodiment, the via layer VIA may be disposed on the protective layer PV and may planarize an upper end of the thin film transistor layer TFTL. The via layer VIA may include an organic insulating material such as polyimide PI.

In an embodiment, the light emitting element layer EML may be disposed on the thin film transistor layer TFTL and may include first to third bank patterns BP1, BP2, and BP3, respectively, first and second electrodes RME1 and RME2, respectively, a first insulating layer PAS1, light emitting elements LD1 and LD2, a bank layer BNL, a second insulating layer PAS2, first to fourth contact electrodes CTE1, CTE2, CTE3, and CTE4, respectively, and a third insulating layer PAS3.

In an embodiment, the bank layer BNL may define a light emitting area EMA and may surround an area where the light emitting elements LD1 and LD2 and the electrodes RME1 and RME2 are disposed.

In an embodiment, the bank patterns BP1, BP2, and BP3 may be spaced apart from each other. The first bank pattern BP1 may be disposed between bank patterns BP2 and BP3. The second bank pattern BP2 may be disposed on the left side of the first bank pattern BP1, and the third bank pattern BP3 may be disposed on the right side of the first bank pattern BP1. Each of the bank patterns BP1, BP2, and BP3 may protrude in an upward direction (Z-axis direction) on the via layer VIA. Each of the bank patterns BP1, BP2, and BP3 may have an inclined side surface.

In an embodiment, a plurality of light emitting elements LD1 and LD2 may be disposed between the bank patterns BP1, BP2, and BP3 that are spaced apart from each other. For example, a first light emitting element LD1 may be disposed between the first bank pattern BP1 and the second bank pattern BP2, and the second light emitting element LD2 may be disposed between the first bank pattern BP1 and the third bank pattern BP3.

In an embodiment, the plurality of light emitting elements LD1 and LD2 include a multilayer insulating film MLO, as illustrated in FIGS. 3 and 4 described above, and the first insulating film INF1 of the multilayer insulating film MLO may have a carbon content of about 3% to about 30%. In an embodiment, the efficiency and reliability of the light emitting elements LD1 and LD2 may be improved by forming the carbon content in the first insulating film INF1 of the light emitting elements LD1 and LD2 to be about 3% to about 30%.

In an embodiment, the first electrode RME1 and the second electrode RME2 may be disposed on the fourth metal layer MTL4. A maximum width of the second electrode RME2 in the second direction DR2 may be greater than a maximum width of the first electrode RME1 in the second direction DR2, but is not limited thereto. The fourth metal layer MTL4 may be disposed on the via layer VIA and the bank patterns BP1, BP2, and BP3.

In an embodiment, the first electrode RME1 and the second electrode RME2 may cover the upper surface and the inclined side surface of one of the bank patterns BP1, BP2, and BP3. The first electrode RME1 and the second electrode RME2 may be reflective electrodes. The fourth metal layer MTL4 may be formed as a single layer or a multi-layer including at least one of molybdenum (Mo), aluminum (Al), chromium (Cr), gold (Au), silver (Ag), titanium (Ti), nickel (Ni), palladium (Pd), indium (In), neodymium (Nd), and copper (Cu). The fourth metal layer MTL4 may include at least one layer including a material with high reflectance. Therefore, each of the first electrode RME1 and the second electrode RME2 may reflect the light emitted from the light emitting elements LD1 and LD2 in the upward direction.

In an embodiment, the first electrode RME1 may be connected to the horizontal voltage line HVDL of the third metal layer MTL3 through a plurality of fifth through holes CNT5. The first electrode RME1 may receive a driving voltage or a high potential voltage from the horizontal voltage line HVDL. The second electrode RME2 may be connected to the second voltage line VSL of the third metal layer MTL3 through a plurality of sixth through holes CNT6. The second electrode RME2 may receive a low potential voltage from the second voltage line VSL.

In an embodiment, the first insulating layer PAS1 may cover the electrodes RME1 and RME2 and may include an inorganic film. The light emitting elements LD1 and LD2 may be insulated from the electrodes RME1 and RME2 by the first insulating layer PAS1. The plurality of light emitting elements LD1 and LD2 may be disposed on the first electrode RME1 and the second electrode RME2.

In an embodiment, the contact electrodes CTE1, CTE2, CTE4, and CTE4 may be disposed on a fifth metal layer MTL5. The contact electrodes CTE1, CTE2, CTE3, and CTE4 may be transparent electrodes. For example, the fifth metal layer MTL5 may include a material such as indium tin oxide (ITO), indium zinc oxide (IZO), or indium tin zinc oxide (ITZO). The fifth metal layer MTL5 may have a stacked structure such as ITO/Ag/ITO, ITO/Ag/IZO, or ITO/Ag/ITZO/IZO, but is not limited thereto.

In an embodiment, the second insulating layer PAS2 may be disposed on the bank layer BNL, the first insulating layer PAS1, and the light emitting element LD. The third insulating layer PAS3 may cover the second insulating layer PAS2 and the contact electrodes CTE1, CTE2, CTE3, and CTE4. The insulating layers PAS2 and PAS3 may include an inorganic film. The insulating layers PAS2 and PAS3 may insulate the contact electrodes CTE1, CTE2, CTE3, and CTE4 from each other. Each of the contact electrodes CTE2, CTE3, and CTE4 may include an air gap disposed in the center, but is not limited thereto.

In an embodiment, the first contact electrode CTE1 may be disposed on the first electrode RME1 and may be connected to the first anode connection electrode ANE1 of the third metal layer MTL3 through a first through hole CNT1. The first contact electrode CTE1 may be connected between the first anode connection electrode ANE1 and one end of the plurality of first light emitting elements LD1. The first contact electrode CTE1 may supply a driving current to the first light emitting element LD1. The first contact electrode CTE1 may correspond to an anode electrode of the plurality of first light emitting elements LD1, but is not limited thereto.

In an embodiment, the second contact electrode CTE2 may be disposed on the second electrode RME2 and may be connected to the other end of the plurality of first light emitting elements LD1. The second contact electrode CTE2 may correspond to a cathode electrode of the plurality of first light emitting elements LD1, but is not limited thereto.

In an embodiment, the third contact electrode CTE3 may be disposed on the first electrode RME1. The third contact electrode CTE3 may be connected to one end of the second light emitting element LD2 and may correspond to an anode electrode of the second light emitting element LD2, but is not limited thereto.

In an embodiment, the fourth contact electrode CTE4 may be disposed on the second electrode RME2 and may be connected to the second voltage line VSL of the third metal layer MTL3 through a fourth through hole CNT4. The fourth contact electrode CTE4 may be connected between the second voltage line VSL and the other end of the second light emitting element LD2. The fourth contact electrode CTE4 may correspond to a cathode electrode of the plurality of second light emitting elements LD2, but is not limited thereto. The fourth contact electrode CTE4 may receive a low potential voltage through the second voltage line VSL.

In an embodiment, in the display device 10 of FIG. 17, two electrodes RME1 and RME2 are spaced apart in parallel and may be disposed on the substrate SUB, and the light emitting element LD may be disposed in a direction that is directed parallel to the upper surface of the substrate SUB. However, the invention is not limited thereto. Depending on the structure of the display device 10, the light emitting element LD may also be disposed in a direction that is perpendicular to the upper surface of the substrate SUB.

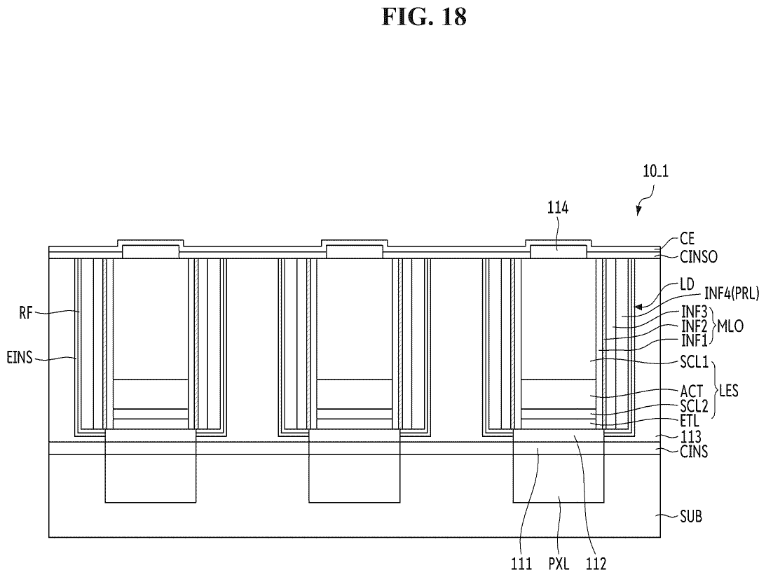

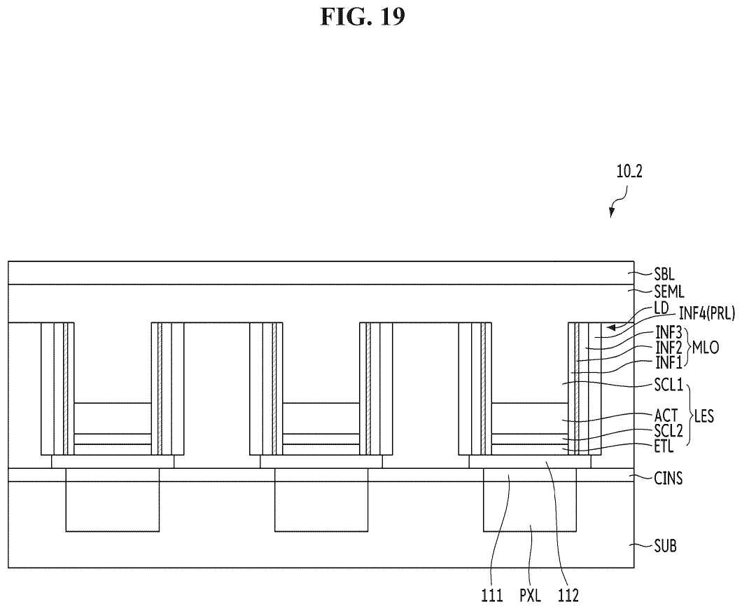

FIGS. 18 and 19 are cross-sectional views of a display device, according to another embodiment.

In an embodiment and referring to FIG. 18, a display device 10_1 may include a plurality of light emitting elements LD spaced apart from each other on the substrate SUB. The light emitting elements LD may be disposed so that a direction in which the semiconductor layers SCL1 and SCL2 are stacked is perpendicular to the upper surface of the substrate SUB.

In an embodiment, the display device 10_1 may include a substrate SUB, a plurality of pixel circuit units PXL formed in the substrate SUB, and a plurality of light emitting elements LD disposed on the substrate SUB.

In an embodiment, the substrate SUB may be a silicon wafer substrate formed using a semiconductor process. The plurality of pixel circuit units PXL of the substrate SUB may be formed using a semiconductor process.

In an embodiment, the plurality of pixel circuit units PXL may be disposed on the front of the display device 10_1, where each of the plurality of pixel circuit units PXL may be connected to a pixel electrode 111 corresponding thereto. That is, the plurality of pixel circuit units PXL and the plurality of pixel electrodes 111 may be connected to each other so as to correspond to each other in a one-to-one manner. Each of the plurality of pixel circuit units PXL may overlap the light emitting element LD in the thickness direction.

In an embodiment, each of the plurality of pixel circuit units PXL may include at least one transistor formed by a semiconductor process. In addition, each of the plurality of pixel circuit units PXL may further include at least one capacitor formed by a semiconductor process. The plurality of pixel circuit units PXL may include, for example, a complementary metal oxide semiconductor (CMOS) circuit. Each of the plurality of pixel circuit units PXL may apply a pixel voltage or an anode voltage to the pixel electrode 111.

In an embodiment, a circuit insulating layer CINS may be disposed on the substrate SUB and may expose each of the pixel electrodes 111 so that the pixel electrodes 111 may be connected to the light emitting element LD. The circuit insulating layer CINS may protect the plurality of pixel circuit units PXL and may planarize a step formed by the pixel electrode 111 disposed on the plurality of pixel circuit units PXL. The circuit insulating layer CINS may include an inorganic insulating material such as silicon oxide (SiOx), silicon nitride (SiNx), silicon oxynitride (SiOxNy), aluminum oxide (AlxOy), or aluminum nitride (AlN).

In an embodiment, the plurality of pixel electrodes 111 may be disposed on the pixel circuit units PXL corresponding thereto, where each of the pixel electrodes 111 may be an electrode exposed from the pixel circuit unit PXL. Each of the pixel electrodes 111 may be formed integrally with the pixel circuit unit PXL. Each of the pixel electrodes 111 may receive the pixel voltage or the anode voltage from the pixel circuit unit PXL. The pixel electrodes 111 may include a metal material such as aluminum (Al).

In an embodiment, the light emitting element layer may be disposed on the substrate SUB and may include connection electrodes 112 and 114, a light emitting element LD, and a common electrode CE. In addition, the light emitting element layer may include a reflective layer RF and a planarization layer 113.

In an embodiment, the first connection electrodes 112 may be disposed on the pixel electrodes 111 corresponding thereto and may include a metal material for adhering the pixel electrodes 111 to the light emitting elements LD. For example, the first connection electrodes 112 may include at least one of gold (Au), copper (Cu), aluminum (Al), and tin (Sn). In another embodiment, the first connection electrodes 112 may include a first layer including any one of gold (Au), copper (Cu), aluminum (Al), and tin (Sn) and a second layer including the other one of gold (Au), copper (Cu), aluminum (Al), and tin (Sn).

In an embodiment, the light emitting element LD may be disposed on the first connection electrode 112 and may be the light emitting element LD described above with reference to FIGS. 1 to 4. The display device 10_1 may include a plurality of light emitting elements LD disposed to respectively correspond to the plurality of pixel electrodes 111 and first connection electrodes 112. The light emitting elements LD may have a shape extending in one direction, and may be disposed so that the one direction is directed perpendicular to the upper surface of the substrate SUB. In an embodiment, the light emitting element LD may be disposed so that the second semiconductor layer SCL2 or the electrode layer ETL faces the first connection electrode 112.

In an embodiment, a reflective layer RF and an element insulating layer EINS may be disposed on a side surface of the light emitting element LD.

In an embodiment, the reflective layer RF may be disposed to surround the multilayer insulating film MLO and the protective film PRL of the light emitting element LD. The reflective layer RF may reflect light emitted from the side surface of the light emitting element LD and emit the light in the upward direction. In an embodiment, the reflective layer RF may include a material with high reflectance. As an example, the reflective layer RF may have a reflectance of about 90% or more in a visible range and may have a thickness of about 5 nm or more.

In an embodiment, the element insulating layer EINS, which is an insulating layer for protecting the reflective layer RF, may be disposed on the reflective layer RF. The element insulating layer EINS may be formed of aluminum oxide (Al₂O₃), but is not limited thereto.

In an embodiment, the planarization layer 113 may be disposed on the circuit insulating layer CINS and may surround the light emitting elements LD. The planarization layer 113 may be a layer for planarizing a step formed by each light emitting element LD and may be formed of an organic film such as an acrylic resin, an epoxy resin, a phenolic resin, a polyamide resin, or a polyimide resin.

In an embodiment, an element insulating film CINS0 may be disposed on the planarization layer 113 and the light emitting element LD. The element insulating film CINS0 may expose each of the light emitting elements LD so that each of the light emitting elements LD may be connected to the common electrode CE. The element insulating film CINS0 may protect the plurality of light emitting elements LD. The element insulating film CINS0 may include a plurality of openings overlapping the light emitting element LD, and a portion of a lower surface of the first semiconductor layer SCL1 of the light emitting element LD may be exposed.

In an embodiment, the second connection electrodes 114 may be disposed on the light emitting elements LD and may include a metal material for adhering the common electrode CE, which will be described later, and the light emitting elements LD. For example, the second connection electrodes 114 may include at least one of gold (Au), copper (Cu), aluminum (Al), and tin (Sn). In another embodiment, the second connection electrodes 114 may include a first layer including any one of gold (Au), copper (Cu), aluminum (Al), and tin (Sn) and a second layer including the other one of gold (Au), copper (Cu), aluminum (Al), and tin (Sn).

In an embodiment, the common electrode CE may be disposed on the second connection electrode 114 and the planarization layer 113, where the common electrode CE may be a common layer commonly formed in a plurality of pixels. The common electrode CE may be made of a transparent conductive material (TCO) such as indium tin oxide (ITO) and indium zinc oxide (IZO) that may transmit light.

In an embodiment and referring to FIG. 19, a display device 10_2 includes a plurality of light emitting elements LD disposed in a vertical direction on the substrate SUB, and the first semiconductor layers SCL1 of the light emitting elements LD may be connected to each other. In the display device 10_2, during the process of manufacturing the light emitting element LD, the first semiconductor material layer 310 may not be completely etched and a portion of a lower end portion thereof may remain, and a plurality of light emitting elements LD may be connected to each other through a common semiconductor layer SEML in which the first semiconductor material layer 310 is not completely etched. In addition, the display device 10_2 may include a semiconductor base layer SBL disposed on the common semiconductor layer SEML. The semiconductor base layer SBL is a layer disposed on an intermediate layer IML of a base substrate BS during the process of manufacturing the light emitting element LD, and the light emitting elements LD may be disposed on the substrate SUB in an integrated state on the semiconductor base layer SBL without being individually separated, to constitute the display device 10_2. The present embodiment is different from the embodiment of FIG. 18 in that the light emitting elements LD are connected to each other and the common electrode CE is omitted.

In an embodiment, the common semiconductor layer SEML may include substantially the same material as the first semiconductor layer SCL1. Different light emitting elements LD may have a shape that protrudes from the common semiconductor layer SEML, and the multilayer insulating film MLO and the protective film PRL may surround the semiconductor layers SCL1 and SCL2 and the active layer ACT protruding from the common semiconductor layer SEML. In the process of manufacturing the light emitting element LD, as the intermediate layer IML is disposed below the semiconductor base layer SBL, the semiconductor base layer SBL may have a low defect density. As described above, the defect density of the semiconductor base layer SBL may be about 1.0 * 10⁸/cm² or less, or about 6 * 10⁷/cm² or less, and the common semiconductor layer SEML, which serves as the common electrode of the light emitting elements LD in the display device 10_2, may also have a low defect density. The light emitting elements LD may be disposed on the substrate SUB in a state connected to each other by the semiconductor base layer SBL of the base substrate BS and the common semiconductor layer SEML without being individually separated during the manufacturing process, and may constitute the display device 10_2.

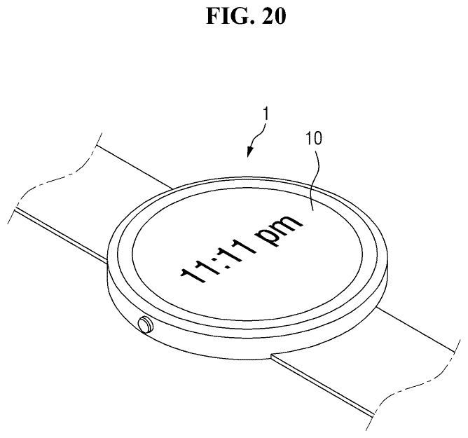

FIGS. 20 to 25 are schematic views illustrating electronic devices including a display device, according to an embodiment.

In an embodiment and referring to FIG. 20, the display device 10 may be applied to a smart watch 1. FIG. 20 illustrates that the smart watch 1 has a circular shape in a plan view, excluding a wrist watch strap. The smart watch 1 includes a circular display device 10 and may follow the planar shape of the display device 10.

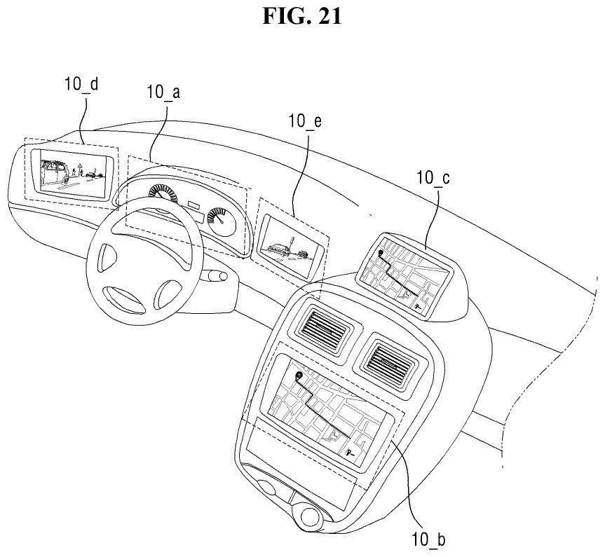

In an embodiment and referring to FIG. 21, display devices 10_a, 10_b, 10_c, 10_d, and 10_e may be applied to an instrument board of a vehicle, applied to a center fascia of the vehicle, or applied to a center information display (CID) disposed on a dashboard of the vehicle. In addition, the display devices, according to an embodiment, may also be applied to a room mirror display substituting for a side mirror of the vehicle.

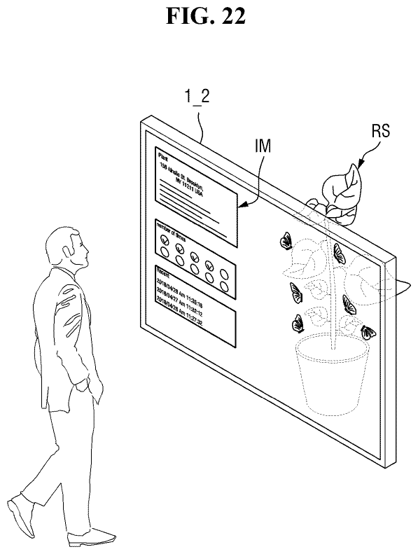

Referring to FIG. 22, the display device, according to an embodiment, may be applied to a transparent display device 1_2, where the transparent display device 1_2 may transmit light while displaying an image IM. Therefore, a user positioned to view a front surface of the transparent display device may not only view the image IM displayed on the display device, but also see an object RS or a background positioned on a rear surface of the transparent display device 1_2. When the display device is applied to the transparent display device 1_2, a substrate of the display device may include a light transmitting portion capable of transmitting light or may be formed of a material capable of transmitting light.

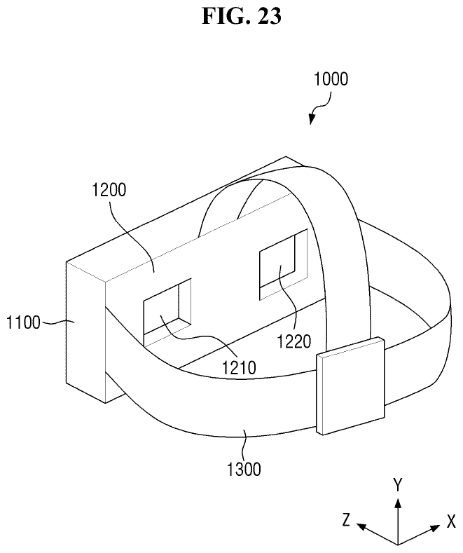

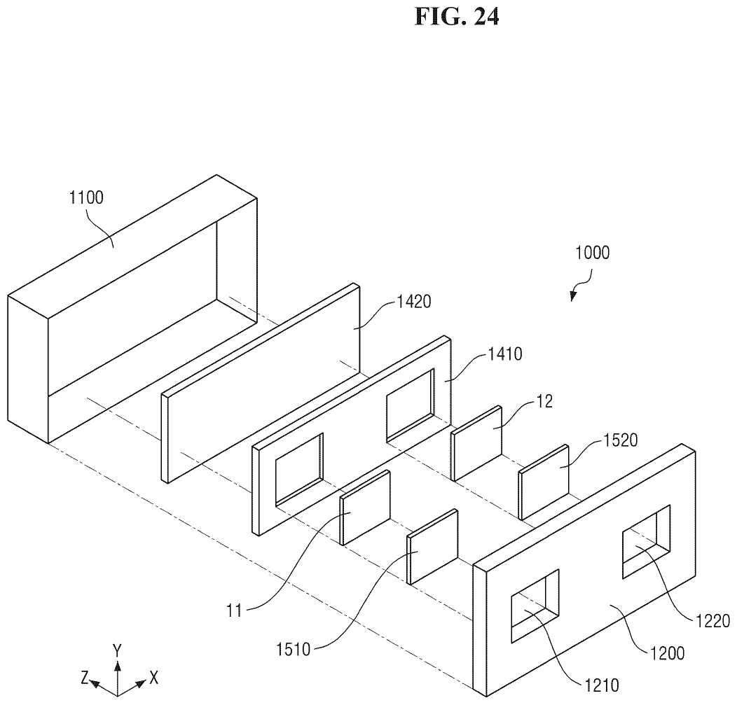

In an embodiment and referring to FIGS. 23 and 24, a head mounted display device 1000 includes a first display device 11, a second display device 12, a display device accommodating portion 1100, an accommodating portion cover 1200, a first eyepiece 1210, a second eyepiece 1220, a head mounting band 1300, a middle frame 1410, a first optical member 1510, a second optical member 1520, a control circuit board 1420, and a connector.

In an embodiment, the first display device 11 provides an image to a user's left eye, and the second display device 12 provides an image to a user's right eye. Since each of the first display device 11 and the second display device 12 is substantially the same as the display device 10 described above, the descriptions of the first display device 11 and the second display device 12 will be omitted.

In an embodiment, the first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

In an embodiment, the middle frame 1410 may be disposed between the first display device 11 and the control circuit board 1420 and may be disposed between the second display device 12 and the control circuit board 1420. The middle frame 1410 serves to support and fix the first display device 11, the second display device 12, and the control circuit board 1420.

In an embodiment, the control circuit board 1420 may be disposed between the middle frame 1410 and the display device accommodating portion 1100. The control circuit board 1420 may be connected to the first display device 11 and the second display device 12 through the connector. The control circuit board 1420 may convert an image source input from the outside into digital video data DATA, and may transmit the digital video data DATA to the first display device 11 and the second display device 12 through the connector.

In an embodiment, the control circuit board 1420 may transmit digital video data DATA corresponding to a left eye image optimized for the user's left eye to the first display device 11, and may transmit digital video data DATA corresponding to a right eye image optimized for the user's right eye to the second display device 12. In another embodiment, the control circuit board 1420 may transmit the same digital video data DATA to the first display device 11 and the second display device 12.

In an embodiment, the display device accommodating portion 1100 serves to accommodate the first display device 11, the second display device 12, the middle frame 1410, the first optical member 1510, the second optical member 1520, the control circuit board 1420, and the connector. The accommodating portion cover 1200 is disposed to cover one opened surface of the display device accommodating portion 1100. The accommodating portion cover 1200 may include a first eyepiece 1210 where the user's left eye is disposed and a second eyepiece 1220 where the user's right eye is disposed. It is illustrated in the drawing that the first eyepiece 1210 and the second eyepiece 1220 are separately disposed, but the invention is not limited thereto. In an embodiment, the first eyepiece 1210 and the second eyepiece 1220 may be integrated into one.

In an embodiment, the first eyepiece 1210 may be aligned with the first display device 11 and the first optical member 1510, and the second eyepiece 1220 may be aligned with the second display device 12 and the second optical member 1520. Therefore, the user may view an image of the first display device 11 magnified as a virtual image by the first optical member 1510 through the first eyepiece 1210 and may view an image of the second display device 12 magnified as a virtual image by the second optical member 1520 through the second eyepiece 1220.

In an embodiment, the head mounting band 1300 serves to fix the display device accommodating portion 1100 to a user's head so that the first eyepiece 1210 and the second eyepiece 1220 of the accommodating portion cover 1200 are disposed proximate to and aligned with the user's left and right eyes, respectively. When the display device accommodating portion 1100 is implemented in a lightweight and small size, the head mounted display device 1000 may include eyeglass frames instead of the head mounting band 1300.

In an embodiment, the head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

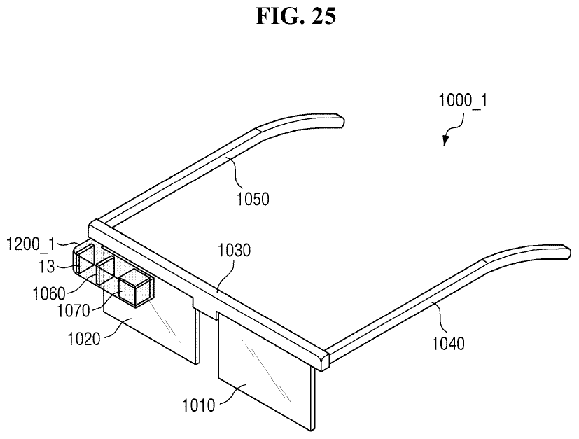

In an embodiment and referring to FIG. 25, a head mounted display device 1000_1 may be an eye glass-type display device in which a display device accommodating portion 1200_1 is implemented in a lightweight and small size. The head mounted display device 1000_1, according to an embodiment, may include a display device 13, a left eye lens 1010, a right eye lens 1020, a support frame 1030, eyeglass frame legs 1040 and 1050, an optical member 1060, a light path conversion member 1070, and a display device accommodating portion 1200_1.

In an embodiment, the display device accommodating portion 1200_1 may include the display device 13, the optical member 1060, and the light path conversion member 1070. As an image displayed on the display device 13 is magnified by the optical member 1060 and a light path thereof is converted by the light path conversion member 1070, the image may be provided to the user's right eye through the right eye lens 1020. Accordingly, the user may view an augmented reality image in which a virtual image displayed on the display device 13 and a real image viewed through the right eye lens 1020 are combined through the right eye.

It is illustrated in the drawing that the display device accommodating portion 1200_1 is disposed at a right distal end of the support frame 1030, but the invention is not limited thereto. For example, the display device accommodating portion 1200_1 may be disposed at a left distal end of the support frame 1030, and in this case, the image of the display device 13 may be provided to the user's left eye. In another embodiment, the display device accommodating portions 1200_1 may be disposed at both the left and right distal ends of the support frame 1030. In this case, the user may view the image displayed on the display device 13 through both the user's left and right eyes.

In concluding the detailed description, those skilled in the art will appreciate that many variations and modifications can be made to the invention without departing from the scope and spirit of the invention. As such, the disclosed embodiments of the invention are used in a generic and descriptive sense only and not for purposes of limitation. Thus, it will be understood by one of ordinary skill in the art to which the invention belongs that the invention may be implemented in other specific embodiments than those described herein without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A light emitting element comprising:
a first semiconductor layer doped with an N-type dopant;
a second semiconductor layer disposed on the first semiconductor layer and doped with a P-type dopant;
an active layer disposed between the first semiconductor layer and the second semiconductor layer;
an electrode layer disposed on the second semiconductor layer; and
a multilayer insulating film surrounding at least an outer surface of the active layer and including two or more layers,
wherein any one insulating film of the multilayer insulating film in contact with at least the outer surface of the active layer has a carbon content of about 3% to about 30%.

2. The light emitting element of claim 1, wherein the multilayer insulating film includes a first insulating film in contact with at least the outer surface of the active layer, and a second insulating film surrounding an outer surface of the first insulating film, wherein the first insulating film has a carbon content of about 3% to about 30%.

3. The light emitting element of claim 1, wherein the any one insulating film includes any one selected from the group consisting of zirconium oxide (ZrO₂), hafnium oxide (HfO₂), lanthanum oxide (La₂O₃), tantalum oxide (Ta₂O₅), yttrium oxide (Y₂O₃), niobium oxide (Nb₂O₅), and titanium oxide (TiO₂).

4. The light emitting element of claim 3, wherein the any one insulating film includes zirconium oxide (ZrO₂) or yttrium oxide (Y₂O₃) and has a film density of about 3 to about 5.

5. The light emitting element of claim 3, wherein the any one insulating film includes hafnium oxide (HfO₂) or tantalum oxide (Ta₂O₅) and has a film density of about 6 to about 8.

6. The light emitting element of claim 3, wherein the any one insulating film includes lanthanum oxide (La₂O₃) and has a film density of about 4 to about 6.

7. The light emitting element of claim 3, wherein the any one insulating film includes niobium oxide (Nb₂O₅) and has a film density of about 2.5 to about 4.5.

8. The light emitting element of claim 3, wherein the any one insulating film includes titanium oxide (TiO₂) and has a film density of about 2 to about 4.

9. The light emitting element of claim 1, wherein the active layer has a diameter of about 0.5 μm to about 6 μm, and has a luminance maintenance rate of about 90% or more compared to an initial luminance when driven continuously for about 300 hours with a first driving current applied.

10. The light emitting element of claim 9, wherein light emitted from the active layer has a peak wavelength in the range of about 440 nm to about 480 nm.

11. The light emitting element of claim 9, wherein the first driving current is about 50 A/cm² or more.

12. A light emitting element comprising:
a light emitting structure including a first semiconductor layer, an active layer, and a second semiconductor layer sequentially disposed along one direction;
a multilayer insulating film surrounding an outer surface of the light emitting structure and including at least two layers of insulating film; and
a protective film surrounding an outer surface of the multilayer insulating film and including at least one insulating film,
wherein a carbon content in any one insulating film of the multilayer insulating film in contact with the outer surface of the light emitting structure is greater than a carbon content in an insulating film that forms an outermost portion of the protective film.

13. The light emitting element of claim 12, wherein the carbon content in the any one insulating film of the multilayer insulating film in contact with the outer surface of the light emitting structure is about 3% to about 30%, and wherein the carbon content in the insulating film that forms the outermost portion of the protective film is about 3% to about 30%.

14. The light emitting element of claim 13, wherein the multilayer insulating film includes a first insulating film surrounding the outer surface of the light emitting structure, a second insulating film surrounding an outer surface of the first insulating film, and a third insulating film surrounding an outer surface of the second insulating film, wherein a carbon content in the first insulating film is about 3% to about 30%.

15. The light emitting element of claim 14, wherein the protective film includes a fourth insulating film surrounding an outer surface of the third insulating film, wherein a carbon content in the fourth insulating film is about 3% to about 30%, and wherein the carbon content in the first insulating film is greater than the carbon content in the fourth insulating film.

16. The light emitting element of claim 14, wherein the protective film includes a fourth insulating film surrounding an outer surface of the third insulating film and a fifth insulating film surrounding an outer surface of the fourth insulating film, wherein a carbon content in the fifth insulating film is about 3% to about 30%, and wherein the carbon content in the first insulating film is greater than the carbon content in the fifth insulating film.

17. A display device comprising:
a first electrode and a second electrode disposed to be spaced apart from each other on a substrate; and
a light emitting element electrically connected to the first electrode and the second electrode, and having a shape extending in one direction,
wherein the light emitting element includes:
a light emitting structure including a first semiconductor layer, an active layer, and a second semiconductor layer sequentially disposed along one direction; and
a multilayer insulating film surrounding an outer surface of the light emitting structure and including at least two layers of insulating film, wherein
any one insulating film of the multilayer insulating film in contact with the outer surface of the light emitting structure has a carbon content of about 3% to about 30%.

18. The display device of claim 17, wherein the any one insulating film in contact with the outer surface of the light emitting structure includes any one selected from the group consisting of zirconium oxide (ZrO₂), hafnium oxide (HfO₂), lanthanum oxide (La₂O₃), tantalum oxide (Ta₂O₅), yttrium oxide (Y₂O₃), niobium oxide (Nb₂O₅), and titanium oxide (TiO₂).

19. The display device of claim 17, further comprising a protective film surrounding an outer surface of the multilayer insulating film and including at least one insulating film,
wherein a carbon content in any one insulating film of the multilayer insulating film in contact with the outer surface of the light emitting structure is greater than a carbon content in an insulating film disposed at an outermost portion of the protective film.

20. The display device of claim 17, wherein the light emitting structure has a diameter of about 0.5 μm to about 6 μm, wherein the light emitting element has a luminance maintenance rate of about 90% or more compared to an initial luminance when driven continuously for about 300 hours with a first driving current of about 50 A/cm² or more applied.
